(19) United States
(12) Patent Application Publication
(10) Pub. No.: US 2024/0397727 A1
(43) Pub. Date: Nov. 28, 2024

(54) SEMICONDUCTOR DEVICE INCLUDING A VERTICAL MEMORY DEVICE AND AN ELECTRONIC SYSTEM INCLUDING THE SEMICONDUCTOR DEVICE

(71) Applicant: SAMSUNG ELECTRONICS CO., LTD., SUWON-SI (KR)

(72) Inventors: Ilho Myeong, Suwon-si (KR); Yongseok Kim, Suwon-si (KR); Sangwoo Han, Suwon-si (KR)

(21) Appl. No.: 18/658,265

(22) Filed: May 8, 2024

(30) Foreign Application Priority Data
May 26, 2023 (KR) 10-2023-0068621
Nov. 14, 2023 (KR) 10-2023-0157685

(51) Int. Cl. H10B 51/20; H01L 25/065; H01L 29/78; H10B 51/10; H10B 80/00

(52) U.S. Cl. CPC H10B 51/20; H01L 25/0652; H01L 29/78391; H10B 51/10; H10B 80/00; H01L 2225/06506

(57) ABSTRACT

A semiconductor device includes: a gate line; a hole extending through the gate line; a channel layer extending lengthwise in a first direction in the hole; a ferroelectric layer arranged between the channel layer and the gate line and extending lengthwise in the first direction in the hole; and a multi-tunneling dielectric structure arranged between the ferroelectric layer and the gate line and extending lengthwise in the first direction in the hole, wherein the multi-tunneling dielectric structure includes: a first silicon oxide film contacting the gate line; a second silicon oxide film spaced apart from the first silicon oxide film in a second direction and contacting the ferroelectric layer, wherein the second direction crosses the first direction; and a silicon oxynitride film disposed between the first silicon oxide film and the second silicon oxide film.

### CROSS-REFERENCE TO RELATED APPLICATION

This application claims priority under 35 U.S.C. § 119 to Korean Patent Application Nos. 10-2023-0068621, filed on May 26, 2023, and 10-2023-0157685, filed on Nov. 14, 2023, in the Korean Intellectual Property Office, the disclosures of which are incorporated by reference herein in their entireties.

### TECHNICAL FIELD

Embodiments of the present inventive concept relate to a semiconductor device and an electronic system including the semiconductor device, and more particularly, to a semiconductor device, which includes a vertical memory device, and an electronic system including the semiconductor device.

### DISCUSSION OF THE RELATED ART

Along with the higher capacity and higher integration of semiconductor devices, vertical memory devices, in which memory capacities are increased by stacking a plurality of memory cells in a vertical direction on substrates, have been under development. Vertical memory devices that include field-effect transistors that include ferroelectrics as gate insulating materials (referred to as ferroelectric gate field-effect transistors (FeFETs) hereinafter) may involve maintaining the electrical stability and reliability of semiconductor devices by securing memory windows represented by characteristics of drain current (Id) versus gate voltage (Vg) (that is, Id-Vg characteristics).

### SUMMARY

According to embodiments of the present inventive concept, a semiconductor device includes: a gate line; a hole extending through the gate line; a channel layer extending lengthwise in a first direction in the hole; a ferroelectric layer arranged between the channel layer and the gate line and extending lengthwise in the first direction in the hole; and a multi-tunneling dielectric structure arranged between the ferroelectric layer and the gate line and extending lengthwise in the first direction in the hole, wherein the multi-tunneling dielectric structure includes: a first silicon oxide film contacting the gate line; a second silicon oxide film spaced apart from the first silicon oxide film in a second direction and contacting the ferroelectric layer, wherein the second direction crosses the first direction; and a silicon oxynitride film disposed between the first silicon oxide film and the second silicon oxide film.

According to embodiments of the present inventive concept, a semiconductor device includes: a stack structure including a plurality of gate lines, which are spaced apart from each other in a vertical direction, and a plurality of insulating patterns alternately arranged with the plurality of gate lines; a channel layer, which extends lengthwise in the vertical direction in a vertical hole that passes through the stack structure in the vertical direction; a ferroelectric layer arranged between the channel layer and the stack structure and extending lengthwise in the vertical direction in the vertical hole; and a multi-tunneling dielectric structure arranged between the ferroelectric layer and the stack structure and extending lengthwise in the vertical direction in the vertical hole, wherein the multi-tunneling dielectric structure includes: a first silicon oxide film contacting the plurality of gate lines; a second silicon oxide film spaced apart from the first silicon oxide film in a horizontal direction and contacting the ferroelectric layer; and a silicon oxynitride film disposed between the first silicon oxide film and the second silicon oxide film.

According to embodiments of the present inventive concept, an electronic system includes: a main substrate; a semiconductor device disposed on the main substrate; and a controller arranged on the main substrate and electrically connected with the semiconductor device, wherein the semiconductor device includes: a gate line; a hole in the gate line; a channel layer extending lengthwise in a first direction in the hole; a ferroelectric layer arranged between the channel layer and the gate line and extending lengthwise in the first direction in the hole; and a multi-tunneling dielectric structure arranged between the ferroelectric layer and the gate line and extending lengthwise in the first direction in the hole, and wherein the multi-tunneling dielectric structure includes: a first silicon oxide film disposed on the gate line; a second silicon oxide film disposed on the ferroelectric layer; and a silicon oxynitride film disposed between the first silicon oxide film and the second silicon oxide film.

### BRIEF DESCRIPTION OF THE DRAWINGS

The above and other aspects of the present inventive concept will become more apparent by describing in detail embodiments thereof, with reference to the accompanying drawings, in which:

FIG. 1 is a block diagram of a semiconductor device according to embodiments of the present inventive concept;

FIG. 2A is a planar layout illustrating components of a cell array structure of a semiconductor device according to embodiments of the present inventive concept;

FIG. 2B is a cross-sectional view of portions of the semiconductor device, taken along the line X1-X1′ of FIG. 2A;

FIG. 2C is an enlarged cross-sectional view of the region EX1 of FIG. 2B;

FIG. 2D is an enlarged plan view of a portion of the region EX1, taken along the line LV1-LV1′ of FIG. 2C;

FIG. 2E is an enlarged cross-sectional view of the region EX2 of FIG. 2C;

FIG. 3 is a cross-sectional view illustrating a semiconductor device according to embodiments of the present inventive concept;

FIG. 4A is a cross-sectional view of a semiconductor device according to embodiments of the present inventive concept, and FIG. 4B is an enlarged plan view of a portion of the semiconductor device, taken along the line LV3-LV3′ of FIG. 4A;

FIGS. 4C and 4D are cross-sectional views respectively illustrating semiconductor devices according to embodiments of the present inventive concept;

FIG. 5 is a cross-sectional view illustrating a semiconductor device according to embodiments of the present inventive concept;

FIG. 6 is a cross-sectional view illustrating a semiconductor device according to embodiments of the present inventive concept;

FIG. 7 is a cross-sectional view illustrating a semiconductor device according to embodiments of the present inventive concept;

FIGS. 8, 9, 10, 11, 12, 13, 14, 15, 16, 17 and 18 are cross-sectional views illustrating a sequence of processes of a method of fabricating a semiconductor device, according to embodiments of the present inventive concept;

FIG. 19 is a cross-sectional view illustrating a method of fabricating a semiconductor device, according to embodiments of the present inventive concept;

FIG. 20 is a diagram schematically illustrating an electronic system including a semiconductor device, according to embodiments of the present inventive concept;

FIG. 21 is a perspective view schematically illustrating an electronic system including a semiconductor device, according to embodiments of the present inventive concept; and

FIG. 22 is a cross-sectional view schematically illustrating semiconductor packages according to embodiments of the present inventive concept.

### DETAILED DESCRIPTION OF THE EMBODIMENTS

Hereinafter, embodiments of the present inventive concept will be described in detail with reference to the accompanying drawings. Like components are denoted by like reference numerals throughout the specification and drawings, and repeated descriptions thereof may be omitted or briefly discussed.

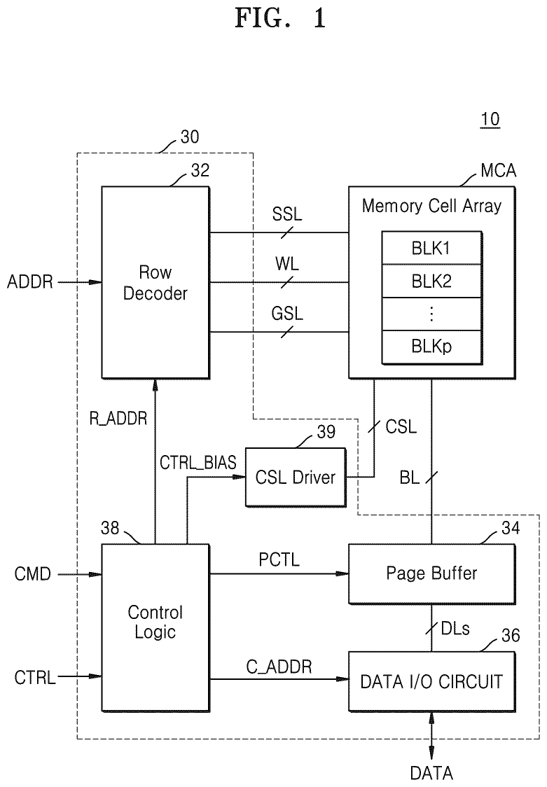

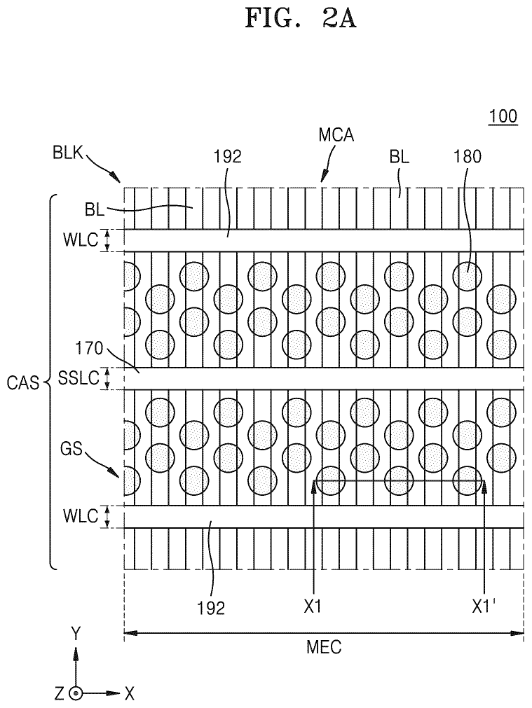

FIG. 1 is a block diagram of a semiconductor device 10 according to embodiments of the present inventive concept.

Referring to FIG. 1, the semiconductor device 10 may include a memory cell array MCA and a peripheral circuit 30. The memory cell array MCA includes a plurality of memory cell blocks BLK1, BLK2, . . . , and BLKp. Each of the plurality of memory cell blocks BLK1, BLK2, . . . , and BLKp may include a plurality of memory cells. A memory cell block BLK1, BLK2, . . . , or BLKp may be connected to the peripheral circuit 30 via a bit line BL, a word line WL, a string select line SSL, and a ground select line GSL.

The peripheral circuit 30 may include a row decoder 32, a page buffer 34, a data input/output circuit 36, a control logic 38, and a common source line driver 39. The peripheral circuit 30 may further include various circuits, such as a voltage generation circuit for generating various voltages required for operations of the semiconductor device 10, an error correction circuit for correcting errors in data read from the memory cell array MCA, an input/output interface, and the like.

The memory cell array MCA may be connected to the row decoder 32 via the word line WL, the string select line SSL, and the ground select line GSL and may be connected to the page buffer 34 via the bit line BL. In the memory cell array MCA, each of the plurality of memory cells, which are included in the plurality of memory cell blocks BLK1, BLK2, . . . , and BLKp, may include a flash memory cell. The memory cell array MCA may include a 3-dimensional memory cell array. The 3-dimensional memory cell array may include a plurality of NAND strings, and each of the plurality of NAND strings may include a plurality of memory cells respectively connected to a plurality of word lines WL that are vertically stacked.

The peripheral circuit 30 may receive an address ADDR, a command CMD, and a control signal CTRL from outside the semiconductor device 10 and may transmit data DATA to and receive the data DATA from a device external to the semiconductor device 10.

The row decoder 32 may select at least one of the plurality of memory cell blocks BLK1, BLK2, . . . , and BLKp in response to the address ADDR that is received from outside the semiconductor device 10 and may select the word line WL, the string select line SSL, and the ground select line GSL of the selected memory cell block. The row decoder 32 may transfer a voltage for performing a memory operation to the word line WL of the selected memory cell block.

The page buffer 34 may be connected to the memory cell array MCA via the bit line BL. The page buffer 34 may apply a voltage to the bit line BL according to the data DATA, which is intended to be stored in the memory cell array MCA, by operating as a write driver during a program operation, and the page buffer 34 may sense the data DATA, which is stored in the memory cell array MCA, by operating as a sense amplifier during a read operation. Program data DATA may be provided to the page buffer 34 via a plurality of data lines DLs. The page buffer 34 may operate according to a control signal PCTL that is provided by the control logic 38.

The data input/output circuit 36 may be connected with the page buffer 34 via a plurality of data lines DLs. During the program operation, the data input/output circuit 36 may receive the data DATA from a memory controller and may provide program data DATA to the page buffer 34, based on a column address C_ADDR provided by the control logic 38. During the read operation, the data input/output circuit 36 may provide read data DATA that is stored in the page buffer 34 to the memory controller, based on the column address C_ADDR that is provided by the control logic 38.

The data input/output circuit 36 may transfer an address or a command, which is input thereto, to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 via a row address line and provide the column address C_ADDR via a column address line to the data input/output circuit 36. The control logic 38 may generate various internal control signals, which are used in the semiconductor device 10, in response to the control signal CTRL. For example, when a memory operation, such as a program operation or an erase operation, is performed, the control logic 38 may adjust levels of voltages respectively provided to the word line WL and the bit line BL.

The common source line driver 39 may be connected to the memory cell array MCA via a common source line CSL. The common source line driver 39 may apply a common source voltage (for example, a power supply voltage) or a ground voltage to the common source line CSL, based on a control signal CTRL_BIAS of the control logic 38.

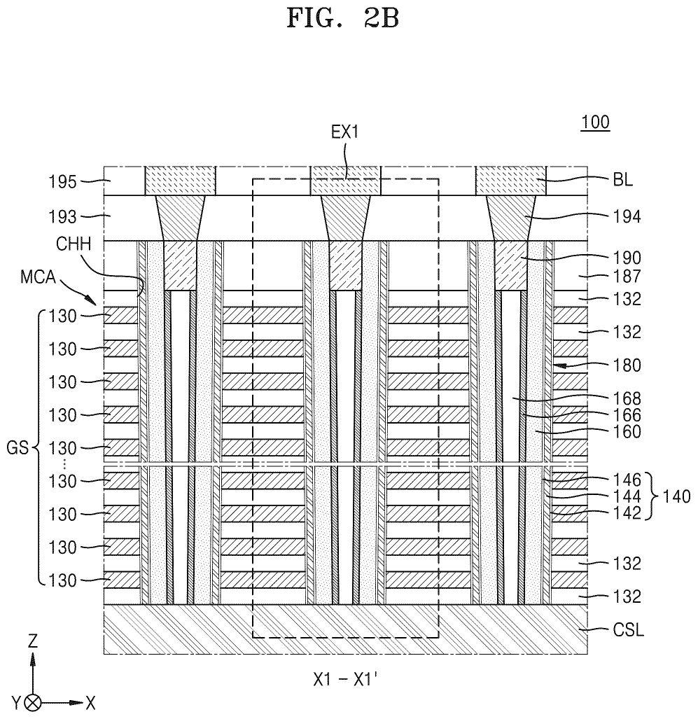

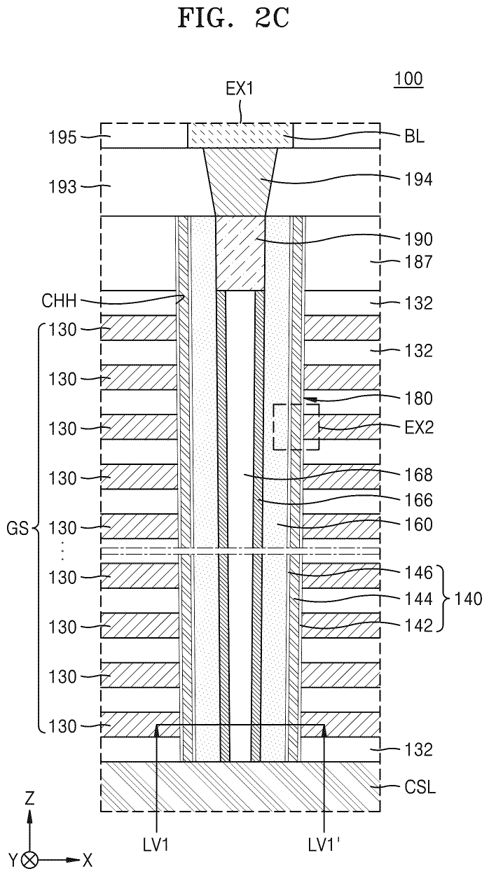

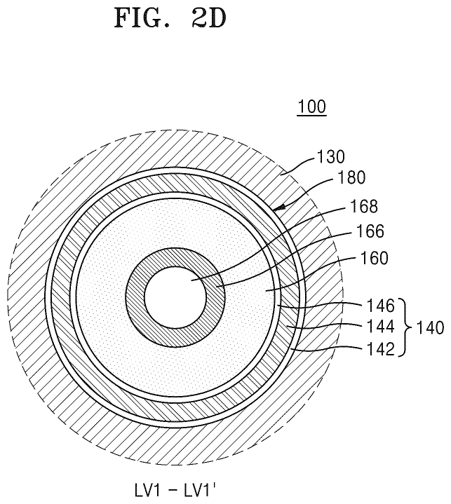

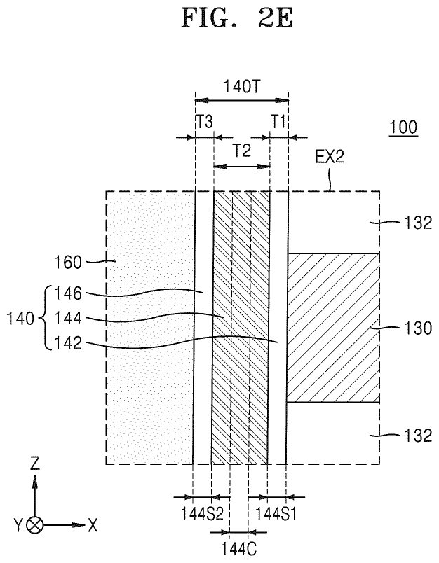

FIG. 2A is a planar layout illustrating components of a cell array structure CAS of a semiconductor device 100 according to embodiments of the present inventive concept. FIG. 2B is a cross-sectional view illustrating portions of the cell array structure CAS of the semiconductor device 100, taken along the line X1-X1′ of FIG. 2A. FIG. 2C is an enlarged cross-sectional view of the region EX1 of FIG. 2B. FIG. 2D is an enlarged plan view of a portion of the region EX1, taken along the line LV1-LV1′ of FIG. 2C. FIG. 2E is an enlarged cross-sectional view of the region EX2 of FIG. 2C. FIGS. 2A and 2B each illustrate components of a memory cell block BLK that corresponds to one selected from the plurality of memory cell blocks BLK1, BLK2, . . . , and BLKp shown in FIG. 1.

Referring to FIGS. 2A to 2E, the semiconductor device 100 may include the cell array structure CAS, and the cell array structure CAS may include the common source line CSL, which is arranged in a memory cell area MEC, and the memory cell array MCA that is arranged over the common source line CSL in the memory cell area MEC.

The memory cell array MCA may include a gate stack GS including a plurality of gate lines 130. The plurality of gate lines 130 of the gate stack GS may extend in a horizontal direction, which is parallel to the common source line CSL, and may overlap each other in the vertical direction (Z direction). The plurality of gate lines 130 may include the plurality of word lines WL, the ground select line GSL, and the string select line SSL, which are shown in FIG. 1.

As shown in FIG. 2B, the cell array structure CAS may include a stack structure, which includes the gate stack GS having an alternating arrangement of the plurality of gate lines 130 and a plurality of insulating patterns 132. The plurality of gate lines 130 overlap each other in the vertical direction (Z direction) over the common source line CSL and are apart from each other in the vertical direction (Z direction). The plurality of insulating patterns 132 may be respectively arranged one-by-one between the common source line CSL and the plurality of gate lines 130 and between the plurality of gate lines 130. The stack structure may further include an intermediate insulating film 187, which covers the uppermost insulating pattern 132 from among the plurality of insulating patterns 132. A gate line 130, which is farthest from the common source line CSL, from among the plurality of gate lines 130 may be covered by the insulating pattern 132 and the intermediate insulating film 187. The plurality of insulating patterns 132 and the intermediate insulating film 187 may each include, for example, silicon oxide, silicon nitride, or SiON.

A plurality of conductive pads 190 may be arranged apart from the common source line CSL in the vertical direction (Z direction) with the stack structure disposed therebetween, and the stack structure includes the plurality of gate lines 130 and the plurality of insulating patterns 132.

Each of the plurality of gate lines 130 may include, for example, a metal, a conductive metal nitride, a metal silicide, an impurity-doped semiconductor, or a combination thereof. For example, each of the plurality of gate lines 130 may include, but is not limited to, tungsten, nickel, cobalt, tantalum, tungsten nitride, titanium nitride, tantalum nitride, doped polysilicon, tungsten silicide, nickel silicide, cobalt silicide, tantalum silicide, or a combination thereof.

The plurality of conductive pads 190 and the common source line CSL may each include a semiconductor material, a metal, a conductive metal nitride, or a combination thereof. For example, the plurality of conductive pads 190 and the common source line CSL may each include, but are not limited to, doped polysilicon, tungsten, titanium, tantalum, copper, aluminum, titanium nitride, tantalum nitride, tungsten nitride, or a combination thereof.

The cell array structure CAS may include a plurality of vertical holes CHH, which pass through the stack structure in the vertical direction (Z direction), and a plurality of channel structures 180, which are respectively arranged in the plurality of vertical holes CHH. The plurality of channel structure 180, which are disposed in the vertical holes CHH, pass through the plurality of gate lines 130 and the plurality of insulating patterns 132 of the stack structure in the vertical direction (Z direction). The plurality of gate lines 130 and the plurality of insulating patterns 132 of the stack structure may respectively define the plurality of vertical holes CHH. For example, the plurality of vertical holes CHH are formed in the plurality of gate lines 130 and the plurality of insulating patterns 132.

Each of the plurality of channel structures 180 may include a multi-tunneling dielectric structure 140, a ferroelectric layer 160, a channel layer 166, and an insulating plug 168 to form a concentric annular structure in the vertical holes CHH and adjacent to the stack of gate lines 130. The multi-tunneling dielectric structure 140, ferroelectric layer 160, channel layer 166, and insulating plug 168, may be sequentially stacked in the stated order in a direction from the plurality of gate lines 130 toward the center of the channel structure 180.

The channel layer 166 may extend lengthwise in the vertical direction (Z direction) in a channel hole CHH. A first end portion of the channel layer 166 may be in contact with a conductive pad 190, and a second end portion of the channel layer 166, opposite to the first end portion, may be in contact with the common source line CSL. The insulating plug 168 may be arranged in a space formed by the channel layer 166 and may be surrounded by an annular shape of the channel layer 166. The ferroelectric layer 160 may extend lengthwise in the vertical direction (Z direction) in the channel hole CHH such that the ferroelectric layer 160 is arranged between the channel layer 166 and the plurality of gate lines 130 of the stack structure and between the channel layer 166 and the plurality of insulating patterns 132 of the stack structure. For example, the ferroelectric layer 160 may have an annular cylindrical shape that may surround the channel layer 166. A first end portion of the ferroelectric layer 160 may be in contact with the conductive pad 190, and a second end portion of the ferroelectric layer 160, opposite to the first end portion, may be in contact with the common source line CSL. The thickness of the ferroelectric layer 160 in the horizontal direction (for example, the X direction and/or the Y direction in FIG. 2A to 2C, or the radial direction from the center of the vertical hole CHH in FIG. 2D) may be substantially constant in the vertical direction (Z direction).

In embodiments of the present inventive concept, the ferroelectric layer 160 may include an oxide of at least one of Hf, Si, Al, Zr, Y, La, Gd, and/or Sr. For example, the ferroelectric layer 160 may include hafnium oxide (HfO), hafnium zirconium oxide (HZO), hafnium titanium oxide, or hafnium silicon oxide. As used herein, the term “HfO” refers to a material including elements contained in the term and is not a chemical formula representing a stoichiometric relationship. For example, the ferroelectric layer 160 may include an HfO₂ film. The ferroelectric layer 160 may further include a dopant, as needed. For example, the dopant may include, but is not limited to, at least one of Si, Al, Zr, Y, La, Gd, Sc, Sr, Mg, and Ba. In embodiments of the present inventive concept, the thickness of the ferroelectric layer 160 in the horizontal direction may range from about 10 nm to about 50 nm; however, the present inventive concept is not limited thereto.

For example, the channel layer 166 may include polysilicon, an oxide semiconductor, a 2-dimensional semiconductor material, or a combination thereof. The polysilicon may include, but is not limited to, doped polysilicon.

The oxide semiconductor, which may be used to constitute the channel layer 166, may be, for example, at least one of InGaZnO (IGZO), Sn—IGZO, InWO (IWO), InZnO (IZO), ZnSnO (ZTO), ZnO, yttrium-doped zinc oxide (YZO), InGaSiO (IGSO), InO, SnO, TiO, ZnON, MgZnO, ZrInZnO, HfInZnO, SnInZnO, SiInZnO, GaZnSnO, ZrZnSnO, or a combination thereof. In embodiments of the present inventive concept, at least a portion of the channel layer 166 may include the same elements as the elements constituting the oxide semiconductor layer and may further include at least one dopant such as aluminum (Al), boron (B), arsenic (As), fluorine (F), and hydrogen (H).

In embodiments of the present inventive concept, the 2-dimensional semiconductor material, which may be used to constitute the channel layer 166, may be, for example, at least one of graphene, black phosphorous, a transition metal chalcogenide, or a combination thereof. The transition metal chalcogenide may include a combination of a transition metal such as Ni, Cu, Zn, Mo, W, Nb, V, Ta, Ti, Zr, Hf, Tc, and Re, and a chalcogen-group element such as S, Se, and Te. For example, the channel layer 166 may include, but is not limited to, MoS₂, MoSe₂, MoTe₂, WS₂, WSe₂, WTe₂, ZrS₂, ZrSe₂, HfS₂, HfSe₂, NbSe₂, ReSe₂, CuS, or a combination thereof.

In embodiments of the present inventive concept, the 2-dimensional semiconductor material, which may be used to constitute the channel layer 166, may include a chalcogenide material including a non-transition metal. For example, the non-transition metal may include at least one of Ga, In, Sn, Ge, or Pb. For example, the channel layer 166 may include, but is not limited to, SnSe₂, GaS, GaSe, GaTe, GeSe, In₂Se₃, InSnS₂, or a combination thereof.

In embodiments of the present inventive concept, the channel layer 166 may include a p-type oxide semiconductor, an n-type oxide semiconductor, or a combination thereof. The p-type oxide semiconductor may include at least one nickel oxide (NiO), copper oxide, tin oxide (SnO), copper aluminum oxide (CuAlO₂), copper chromium oxide (CuCrO₂), beta tellurium dioxide (β-TeO₂), or a combination thereof. For example, the copper oxide may include, but is not limited to, CuO or Cu₂O. For example, the n-type oxide semiconductor may include at least one of indium oxide (In₂O₃), tin oxide (SnO₂), zinc oxide (ZnO), IGZO, or a combination thereof. The tin oxide may exhibit p-type characteristics when existing in the form of SnO and may exhibit n-type characteristics when existing in the form of SnO₂.

In embodiments of the present inventive concept, to adjust the carrier mobility in the channel layer 166, the channel layer 166 may further include a p-type dopant or an n-type dopant. For example, the channel layer 166 may have, but is not limited to, a thickness of about 10 nm to about 20 nm in the horizontal direction.

The channel layer 166 may have an annular cylindrical shape to define a columnar space therein, and the columnar space extends lengthwise in the vertical direction (Z direction). The channel layer 166 may be in contact with one conductive pad 190 selected from the plurality of conductive pads 190.

The insulating plug 168 may be arranged in the columnar space defined by the channel layer 166. The insulating plug 168 may fill a space between the conductive pad 190 and the common source line CSL in the columnar space that is defined by the channel layer 166. The insulating plug 168 may have a surface contacting an inner sidewall of the channel layer 166. For example, the insulating plug 168 may include, but is not limited to, a silicon oxide film.

The multi-tunneling dielectric structure 140 may extend lengthwise in the vertical direction (Z direction) in the vertical hole CHH such that the multi-tunneling dielectric structure 140 is arranged between the ferroelectric layer 160 and the plurality of gate lines 130 of the stack structure and between the ferroelectric layer 160 and the plurality of insulating patterns 132 of the stack structure. The multi-tunneling dielectric structure 140 may have a triple-layer structure including a first silicon oxide film 142, a silicon oxynitride film 144, and a second silicon oxide film 146, which are sequentially stacked in the stated order from the plurality of gate lines 130 toward the inside of the vertical hole CHH. For example, the first silicon oxide film 142, silicon oxynitride film 144, and second silicon oxide film 146 may form a concentric annular cylindrical structure that extends in the vertical direction (Z direction). The first silicon oxide film 142 may be in contact with the plurality of gate lines 130. The second silicon oxide film 146 may be spaced apart from the first silicon oxide film 142 in the horizontal direction and in contact with the ferroelectric layer 160. The silicon oxynitride film 144 may be arranged between the first silicon oxide film 142 and the second silicon oxide film 146 and may have a sidewall contacting the first silicon oxide film 142 and a sidewall contacting the second silicon oxide film 146.

In the multi-tunneling dielectric structure 140, each of the first silicon oxide film 142, the silicon oxynitride film 144, and the second silicon oxide film 146 may have an annular cylindrical shape (e.g., a hollow cylinder). The second silicon oxide film 146 may be arranged in a space defined by the silicon oxynitride film 144, and the second silicon oxide film 146 and the silicon oxynitride film 144 may be arranged in a space defined by the first silicon oxide film 142. The channel layer 166 may be arranged in a space defined by the second silicon oxide film 146.

As shown in FIG. 2E, in the multi-tunneling dielectric structure 140, a thickness T2 of the silicon oxynitride film 144 in the horizontal direction may be greater than a thickness T1 of the first silicon oxide film 142 in the horizontal direction and greater than a thickness T3 of the second silicon oxide film 146 in the horizontal direction. In embodiments of the present inventive concept, in the horizontal direction, the thickness T1 of the first silicon oxide film 142 and the thickness T3 of the second silicon oxide film 146 may be equal to or similar to each other. For example, a thickness 140T of the multi-tunneling dielectric structure 140 in the horizontal direction may be about 3 nm to about 5 nm. For example, the thickness T2 of the silicon oxynitride film 144 in the horizontal direction may be about 2 nm to about 3 nm. For example, each of the thickness T1 of the first silicon oxide film 142 and the thickness T3 of the second silicon oxide film 146 may be about 0.5 nm to about 1.5 nm. However, the thickness of the multi-tunneling dielectric structure 140 and the respective thicknesses of the first silicon oxide film 142, the silicon oxynitride film 144, and the second silicon oxide film 146, which are included in the multi-tunneling dielectric structure 140, are not limited to the examples set forth above and may be variously changed without departing from the spirit and scope of the present inventive concept.

In the silicon oxynitride film 144 of the multi-tunneling dielectric structure 140, the nitrogen atom content in the silicon oxynitride film 144 may gradually increase toward a center portion 144C of the silicon oxynitride film 144, which corresponds to a portion of the silicon oxynitride film 144 at an approximately middle position that is between the first silicon oxide film 142 and the second silicon oxide film 146. For example, the center portion 144C may correspond to a portion of the silicon oxynitride film 144 at an approximately middle position between the first silicon oxide film 142 and the second silicon oxide film 146, in a plan view (for example, the plan view shown in FIG. 2D). For example, toward the center portion 144C of the silicon oxynitride film 144 in the horizontal direction (for example, the radial direction from an outer sidewall of the silicon oxynitride film 144 toward the center of the vertical hole CHH in FIG. 2D) from the outer sidewall of the silicon oxynitride film 144, which is in contact with the first silicon oxide film 142, and also toward the center portion 144C of the silicon oxynitride film 144 in the horizontal direction (for example, the radial direction from the inner sidewall of the silicon oxynitride film 144 toward the outside of the vertical hole CHH in FIG. 2D) from the inner sidewall of the silicon oxynitride film 144, which is in contact with the second silicon oxide film 146, the nitrogen atom content in the silicon oxynitride film 144 may gradually increase.

As described above, when the nitrogen atom content in the silicon oxynitride film 144 gradually increases toward the center portion 144C of the silicon oxynitride film 144, a first side portion 144S1 of the silicon oxynitride film 144, which is in contact with or adjacent to the first silicon oxide film 142, and a second side portion 144S2 of the silicon oxynitride film 144, which is in contact with or adjacent to the second silicon oxide film 146, may each include oxygen-rich SiON, and the center portion 144C of the silicon oxynitride film 144, which is apart from each of the first silicon oxide film 142 and the second silicon oxide film 146, may include nitrogen-rich SiON. Herein, the oxygen-rich SiON, which is included in the first side portion 144S1, may be referred to as a first oxygen-rich SiON, and the oxygen-rich SiON, which is included in the second side portion 144S2, may be referred to as a second oxygen-rich SiON.

As used herein, the term “oxygen-rich SiON” refers to a material, which includes the element Si, the element O, and the element N, and in which the content of the element O is greater than the content of the element N, and the term “nitrogen-rich SiON” refers to a material, which includes the element Si, the element O, and the element N, and in which the content of the element N is greater than the content of the element O.

In the cell array structure CAS, a plurality of bit lines BL may be arranged over the plurality of channel structures 180. A plurality of bit line contact pads 194 may be arranged between the plurality of channel structures 180 and the plurality of bit lines BL. The conductive pad 190, which is arranged on one end of each of the plurality of channel structures 180, may be connected to one bit line BL corresponding thereto from among the plurality of bit lines BL via a bit line contact pad 194. The plurality of bit line contact pads 194 may be insulated from each other by a first upper insulating film 193.

A portion of the ferroelectric layer 160 may be arranged between the conductive pad 190 and the first upper insulating film 193. The plurality of bit lines BL may be insulated from each other by a second upper insulating film 195. The plurality of bit line contact pads 194 and the plurality of bit lines BL may each include a metal, a conductive metal nitride, or a combination thereof. For example, the plurality of bit line contact pads 194 and the plurality of bit lines BL may each include tungsten, titanium, tantalum, copper, aluminum, titanium nitride, tantalum nitride, tungsten nitride, or a combination thereof. Each of the first upper insulating film 193 and the second upper insulating film 195 may include a silicon oxide film, a silicon nitride film, or a combination thereof.

As shown in FIG. 2A, in the cell array structure CAS, a plurality of word line cut regions WLC may extend in a first horizontal direction (X direction). The plurality of word line cut regions WLC may define the width of the gate stack GS in a second horizontal direction (Y direction). The plurality of word line cut regions WLC may each be filled with a word line cut structure 192. The word line cut structure 192 may include, for example, an insulating film, polysilicon, a metal film, or a combination thereof. In embodiments of the present inventive concept, the word line cut structure 192 may include, but is not limited to, a silicon oxide film, a silicon nitride film, a polysilicon film, a tungsten film, or a combination thereof.

In the memory cell array MCA, two string select lines SSL (see FIG. 1) that are adjacent to each other in the second horizontal direction (Y direction) may be spaced apart from each other with a string select line cut region SSLC therebetween. The string select line cut region SSLC may be filled with an insulating film 170. The insulating film 170 may include, for example, an oxide film, a nitride film, or a combination thereof. In embodiments of the present inventive concept, at least a portion of the string select line cut region SSLC may be filled with an air gap. As used herein, the term “air” may refer to the atmosphere, or other gases that may be present during a fabrication process.

Each of the plurality of channel structures 180 of the semiconductor device 100 described with reference to FIGS. 2A to 2E includes the multi-tunneling dielectric structure 140, the ferroelectric layer 160, the channel layer 166, and the insulating plug 168, which are stacked in the stated order in the direction from the plurality of gate lines 130 toward the center of the channel structure 180, and the multi-tunneling dielectric structure 140 has a triple-layer structure including the first silicon oxide film 142, the silicon oxynitride film 144, and the second silicon oxide film 146, which are stacked in the stated order from the plurality of gate lines 130 toward the inside of the vertical hole CHH.

In embodiments of the present inventive concept, during a program operation of the semiconductor device 100, a program voltage may be applied from the gate line 130 to the channel layer 166 across the multi-tunneling dielectric structure 140 and the ferroelectric layer 160, and here, the ferroelectric layer 160 may have a polarity of a program state. During an erase operation of the semiconductor device 100, an erase voltage may be applied from the gate line 130 to the channel layer 166 across the multi-tunneling dielectric structure 140 and the ferroelectric layer 160, and here, the ferroelectric layer 160 may have a polarity of an erase state. Because the multi-tunneling dielectric structure 140 of the semiconductor device 100 has a triple-layer structure including the first silicon oxide film 142, the silicon oxynitride film 144, and the second silicon oxide film 146, charge trapping may occur in the silicon oxynitride film 144 as well as at an interface between the ferroelectric layer 160 and the second silicon oxide film 146, during the program operation of the semiconductor device 100. Therefore, the trapping rate and the trapping amount in the multi-tunneling dielectric structure 140 may be increased, and thus, the operation speed of the semiconductor device 100 may increase.

In addition, the multi-tunneling dielectric structure 140 of the semiconductor device 100 has a triple-layer structure including the first silicon oxide film 142, the silicon oxynitride film 144, and the second silicon oxide film 146, and the nitrogen atom content in the silicon oxynitride film 144 may gradually increase, toward the center portion 144C of the silicon oxynitride film 144 from the outer sidewall of the silicon oxynitride film 144, which is in contact with the first silicon oxide film 142, and also toward the center portion 144C of the silicon oxynitride film 144 from the inner sidewall of the silicon oxynitride film 144, which is in contact with the second silicon oxide film 146. Therefore, there may be a large number of phase transition layers of silicon oxynitride (SiON) in the silicon oxynitride film 144. Because a large amount of charge may be trapped by the large number of phase transition layers in the silicon oxynitride film 144, the electron and hole transport symmetry in the semiconductor device 100 may improve, and a memory window represented by characteristics of drain current (Id) versus gate voltage (Vg) (that is, Id-Vg characteristics) may be increased even at a relatively low programming voltage. Therefore, the semiconductor device 100, which constitutes a vertical memory device including memory cells that are 3-dimensionally arranged in an area that is reduced due to down-scaling, may have increased electrical stability and reliability.

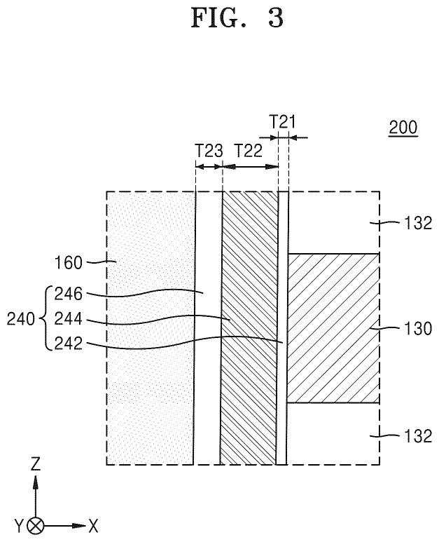

FIG. 3 is a cross-sectional view illustrating a semiconductor device 200 according to embodiments of the present inventive concept. FIG. 3 illustrates an enlarged cross-sectional configuration of a portion of the semiconductor device 200, which corresponds to the region EX2 of FIG. 2C. In FIG. 3, the same reference numerals as in FIGS. 2A to 2E respectively denote the same members, and here, repeated descriptions thereof may be omitted or briefly discussed.

Referring to FIG. 3, the semiconductor device 200 may have substantially the same configuration as the semiconductor device 100 described with reference to FIGS. 2A to 2E. However, the semiconductor device 200 includes a multi-tunneling dielectric structure 240 instead of the multi-tunneling dielectric structure 140 of the semiconductor device 100.

The multi-tunneling dielectric structure 240 may have substantially the same configuration as the multi-tunneling dielectric structure 140 described with reference to FIGS. 2B to 2E. However, the multi-tunneling dielectric structure 240 may have a triple-layer structure including a first silicon oxide film 242, a silicon oxynitride film 244, and a second silicon oxide film 246, which are sequentially stacked in the stated order from the gate line 130 toward the ferroelectric layer 160. The first silicon oxide film 242 may be in contact with the gate line 130. The second silicon oxide film 246 may be spaced apart from the first silicon oxide film 242 in the horizontal direction (for example, the X direction in FIG. 3) and may be in contact with the ferroelectric layer 160. The silicon oxynitride film 244 may be arranged between the first silicon oxide film 242 and the second silicon oxide film 246 and may have a sidewall contacting the first silicon oxide film 242 and a sidewall contacting the second silicon oxide film 246.

In the multi-tunneling dielectric structure 240, each of the first silicon oxide film 242, the silicon oxynitride film 244, and the second silicon oxide film 246 may have an annular cylindrical shape. A thickness T22 of the silicon oxynitride film 244 in the horizontal direction may be greater than a thickness T21 of the first silicon oxide film 242 in the horizontal direction and greater than a thickness T23 of the second silicon oxide film 246 in the horizontal direction. In the horizontal direction, the thickness T21 of the first silicon oxide film 242 may be different from the thickness T23 of the second silicon oxide film 246.

In embodiments of the present inventive concept, the thickness T23 of the second silicon oxide film 246 may be greater in the horizontal direction than the thickness T21 of the first silicon oxide film 242. As such, because the thickness T23 of the second silicon oxide film 246 is greater than the thickness T21 of the first silicon oxide film 242, the ferroelectric layer 160 may be in contact with the second silicon oxide film 246 having the thickness T23 that is relatively great. Therefore, when a program voltage is applied from the gate line 130 to the channel layer 166 (see FIG. 2C) across the multi-tunneling dielectric structure 240 and the ferroelectric layer 160, the second silicon oxide film 246 may prevent electrons or holes that are trapped at an interface between the ferroelectric layer 160 and the second silicon oxide film 246 from exiting again toward the gate line 130.

In embodiments of the present inventive concept, the thickness of the multi-tunneling dielectric structure 240 in the horizontal direction may be about 3 nm to about 5 nm. For example, the thickness T22 of the silicon oxynitride film 244 in the horizontal direction may be about 2 nm to about 3 nm. For example, the thickness T21 of the first silicon oxide film 242 may be about 0.5 nm to about 1 nm. For example, the thickness T23 of the second silicon oxide film 246 may have a value that is greater than the thickness T21 of the first silicon oxide film 242 and may be selected from a range of about 1 nm to about 2 nm. However, the present inventive concept is not limited to the thickness ranges set forth above and may be variously modified and changed.

In embodiments of the present inventive concept, unlike the example shown in FIG. 3, the thickness T21 of the first silicon oxide film 242 may be greater in the horizontal direction than the thickness T23 of the second silicon oxide film 246.

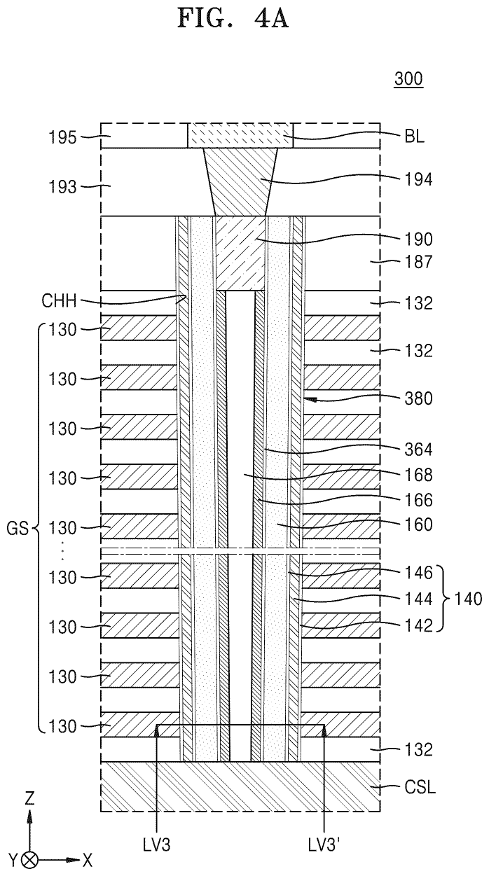

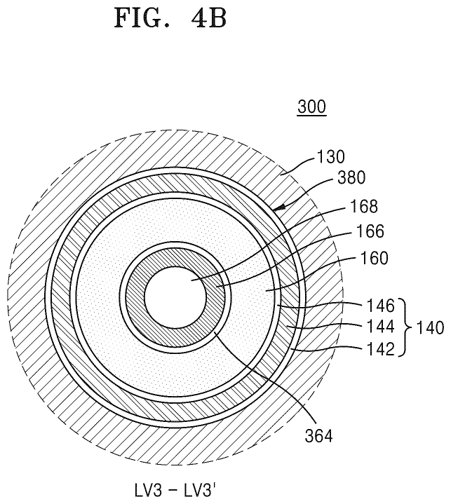

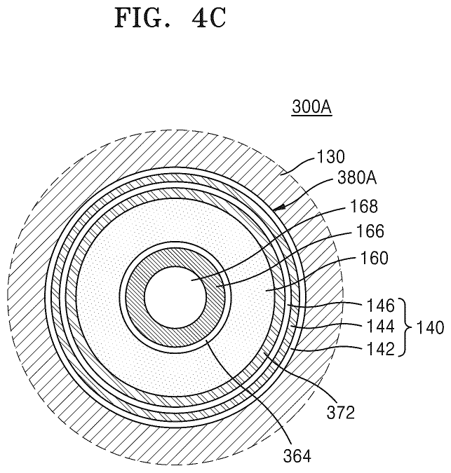

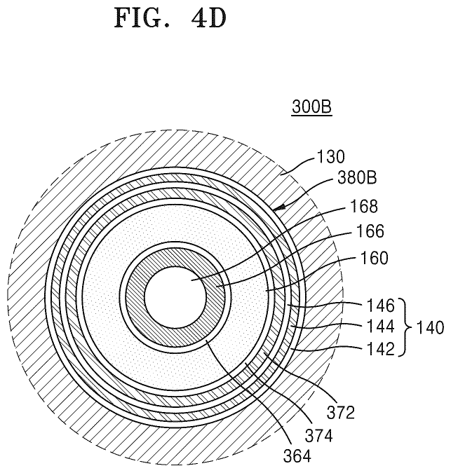

FIGS. 4A and 4B are diagrams illustrating a semiconductor device 300 according to embodiments of the present inventive concept, and in particular, FIG. 4A is an enlarged cross-sectional view of a portion of the semiconductor device 300, which corresponds to the region EX1 of FIG. 2B, and FIG. 4B is an enlarged plan view of a portion of the semiconductor device 300, taken along the line LV3-LV3′ of FIG. 4A. In FIGS. 4A and 4B, the same reference numerals as in FIGS. 2A to 2E respectively denote the same members, and here, repeated descriptions thereof may be omitted or briefly discussed.

Referring to FIGS. 4A and 4B, the semiconductor device 300 may have substantially the same configuration as the semiconductor device 100 described with reference to FIGS. 2A to 2E. However, the semiconductor device 300 includes a channel structure 380 instead of the channel structure 180 of the semiconductor device 100.

The channel structure 380 may have substantially the same configuration as the channel structure 180 described with reference to FIGS. 2A to 2E. However, the channel structure 380 further includes a channel oxide film 364 between the channel layer 166 and the ferroelectric layer 160, and the channel oxide film 364 may separate the channel layer 166 from the ferroelectric layer 160. The channel oxide film 364 may extend lengthwise in the vertical direction (Z direction) in the vertical hole CHH. The channel oxide film 364 may have a cylindrical shape surrounding the channel layer 166. For example, the channel oxide film 364 may have an annular cylindrical shape. The channel oxide film 364 may include an inner sidewall contacting the channel layer 166 and an outer sidewall contacting the ferroelectric layer 160.

The channel oxide film 364 may be spaced apart from the multi-tunneling dielectric structure 140 in the horizontal direction (for example, the radial direction from the center of the vertical hole CHH in FIG. 4B) with the ferroelectric layer 160 therebetween. The channel layer 166 and the channel oxide film 364 may be arranged in a space defined by the ferroelectric layer 160.

In embodiments of the present inventive concept, the channel oxide film 364 may include a silicon oxide film, a silicon oxynitride film, a high-K film having a dielectric constant that is higher than that of the silicon oxide film, or a combination thereof. The high-K film may include a metal oxide film. For example, the high-K film may include, but is not limited to, an Al₂O₃ film. In embodiments of the present inventive concept, the thickness of the channel oxide film 364 may be selected from, but is not limited to, a range of about 0.1 nm to about 20 nm.

In the semiconductor device 300 described with reference to FIGS. 4A and 4B, when the channel oxide film 364 includes a high-K film, the channel oxide film 364 may provide a relatively small effective oxide film thickness even when the channel oxide film 364 has a relatively great physical thickness. Therefore, a high-K film having a relatively great physical thickness may be used as the channel oxide film 364. As such, in the semiconductor device 300 including the channel oxide film 364, which includes a high-K film having a relatively great physical thickness, when a program voltage is applied from the gate line 130 to the channel layer 166 across the multi-tunneling dielectric structure 140, the ferroelectric layer 160, and the channel oxide film 364, the channel oxide film 364 may prevent electrons or holes, which have flowed in the channel layer 166, from exiting again toward the gate line 130.

FIGS. 4C and 4D are cross-sectional views respectively illustrating semiconductor devices 300A and 300B according to embodiments of the present inventive concept. FIGS. 4C and 4D respectively illustrate enlarged planar configurations of portions of the semiconductor devices 300A and 300B, which correspond to the region taken along the line LV3-LV3′ in FIG. 4A. In FIGS. 4C and 4D, the same reference numerals as in FIGS. 2A to 4B respectively denote the same members, and here, repeated descriptions thereof may be omitted or briefly discussed.

Referring to FIG. 4C, the semiconductor device 300A may have substantially the same configuration as the semiconductor device 300 described with reference to FIGS. 4A and 4B. However, the semiconductor device 300A includes a channel structure 380A instead of the channel structure 380 of the semiconductor device 300.

The channel structure 380A may have substantially the same configuration as the channel structure 380 described with reference to FIGS. 4A and 4B. However, the channel structure 380A further includes a silicon nitride film 372 between the multi-tunneling dielectric structure 140 and the ferroelectric layer 160. The silicon nitride film 372 may have an annular cylindrical shape surrounding the ferroelectric layer 160. The silicon nitride film 372 may include an inner sidewall, which is in contact with the ferroelectric layer 160, and an outer sidewall, which is in contact with the second silicon oxide film 146 of the multi-tunneling dielectric structure 140. The silicon nitride film 372 may be spaced apart from the silicon oxynitride film 144 with the second silicon oxide film 146 disposed therebetween.

Referring to FIG. 4D, the semiconductor device 300B may have substantially the same configuration as the semiconductor device 300 described with reference to FIGS. 4A and 4B. However, the semiconductor device 300B includes a channel structure 380B instead of the channel structure 380 of the semiconductor device 300.

The semiconductor device 300B may have substantially the same configuration as the channel structure 380 described with reference to FIGS. 4A and 4B. However, the semiconductor device 300B further includes a silicon nitride film 372 and a third silicon oxide film 374, which are arranged between the multi-tunneling dielectric structure 140 and the ferroelectric layer 160 and sequentially stacked in the stated order from the multi-tunneling dielectric structure 140 toward the ferroelectric layer 160. The silicon nitride film 372 may be arranged between the multi-tunneling dielectric structure 140 and the third silicon oxide film 374. The third silicon oxide film 374 may be arranged between the silicon nitride film 372 and the ferroelectric layer 160.

The third silicon oxide film 374 may have an annular cylindrical shape surrounding the ferroelectric layer 160. The silicon nitride film 372 may have an annular cylindrical shape surrounding the third silicon oxide film 374. The silicon nitride film 372 may include an inner sidewall, which is in contact with the third silicon oxide film 374, and an outer sidewall, which is in contact with the second silicon oxide film 146 of the multi-tunneling dielectric structure 140. The third silicon oxide film 374 may include an inner sidewall, which is in contact with the ferroelectric layer 160, and an outer sidewall, which is in contact with the silicon nitride film 372. The third silicon oxide film 374 may be spaced apart from the second silicon oxide film 146 of the multi-tunneling dielectric structure 140 with the silicon nitride film 372 disposed therebetween. The silicon nitride film 372 may be spaced apart from the silicon oxynitride film 144 with the second silicon oxide film 146 of the multi-tunneling dielectric structure 140 disposed therebetween.

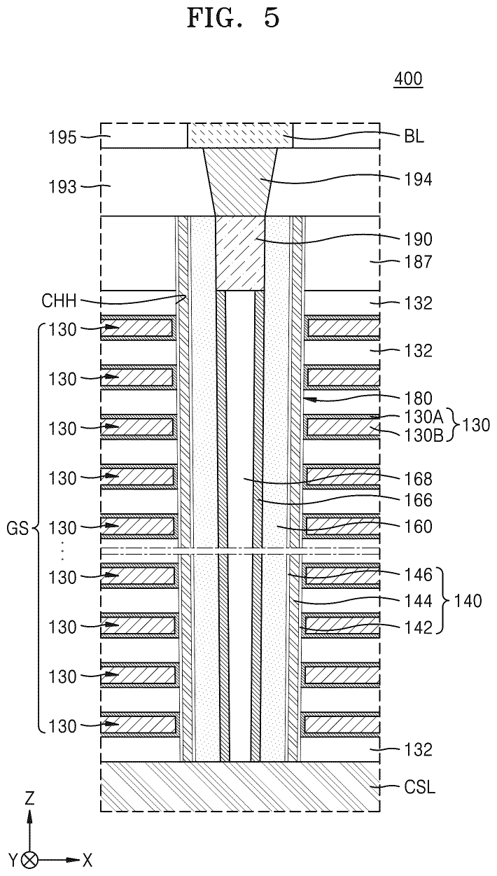

FIG. 5 is a cross-sectional view illustrating a semiconductor device 400 according to embodiments of the present inventive concept. FIG. 5 illustrates an enlarged configuration of a portion of the semiconductor device 400, which corresponds to the region EX1 of FIG. 2B. In FIG. 5, the same reference numerals as in FIGS. 2A to 2E respectively denote the same members, and here, repeated descriptions thereof may be omitted or briefly discussed.

Referring to FIG. 5, the semiconductor device 400 may have substantially the same configuration as the semiconductor device 100 described with reference to FIGS. 2A to 2E. However, in the semiconductor device 400, each of the plurality of gate lines 130 may include a conductive barrier film 130A and a metal film 130B that is surrounded by the conductive barrier film 130A. In embodiments of the present inventive concept, the conductive barrier film 130A may include a TiN film or a TaN film, and the metal film 130B may include a W film, a Mo film, or a Ru film, but the present inventive concept is not limited thereto.

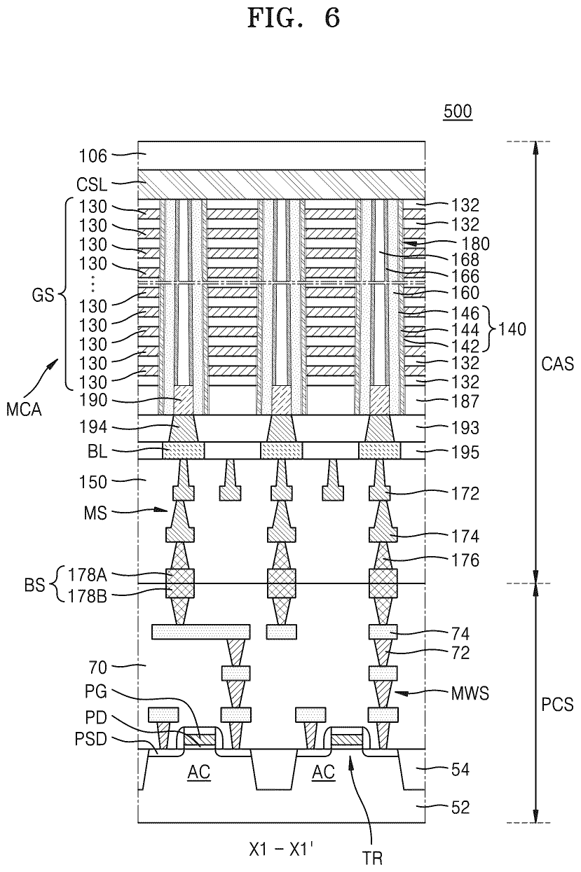

FIG. 6 is a cross-sectional view illustrating a semiconductor device 500 according to embodiments of the present inventive concept. In FIG. 6, the same reference numerals as in FIGS. 2A to 2E respectively denote the same members, and here, repeated descriptions thereof may be omitted or briefly discussed.

Referring to FIG. 6, the semiconductor device 500 may include the cell array structure CAS and a peripheral circuit structure PCS, which overlap each other in the vertical direction (Z direction). The cell array structure CAS may include the memory cell area MEC in which the memory cell array MCA is arranged.

In embodiments of the present inventive concept, the semiconductor device 500 may have a chip-to-chip (C2C) structure. The C2C structure may be a structure obtained by forming the cell array structure CAS on a first wafer, followed by forming the peripheral circuit structure PCS on a second wafer that is different from the first wafer, and then, by connecting the cell array structure CAS and the peripheral circuit structure PCS to each other by a bonding method. For example, the bonding method may refer to a method of bonding a first bonding metal pad 178A, which is formed in an uppermost metal layer of the cell array structure CAS, to a second bonding metal pad 178B, which is formed in an uppermost metal layer of the peripheral circuit structure PCS, to allow the first bonding metal pad 178A and the second bonding metal pad 178B to be electrically connected to each other. In embodiments of the present inventive concept, when each of the first bonding metal pad 178A and the second bonding metal pad 178B includes copper (Cu), the bonding method may be referred to as a Cu—Cu bonding method. In embodiments of the present inventive concept, each of the first bonding metal pad 178A and the second bonding metal pad 178B may include aluminum (Al) or tungsten (W).

The gate stack GS, which includes the plurality of gate lines 130 of the memory cell array MCA, may be arranged between the common source line CSL and the peripheral circuit structure PCS.

The peripheral circuit structure PCS may include a substrate 52, a plurality of circuits formed on the substrate 52, and a multilayer wiring structure MWS for connecting the plurality of circuits to each other or connecting the plurality of circuits to components in the memory cell area MEC of the cell array structure CAS.

The substrate 52 may include a semiconductor substrate. For example, the substrate 52 may include Si, Ge, or SiGe. An active region AC may be defined in the substrate 52 by a device isolation film 54. A plurality of transistors TR constituting the plurality of circuits may be formed on the active region AC. Each of the plurality of transistors TR may include a gate dielectric film PD and a gate PG, which are sequentially stacked in the stated order on the substrate 52, and a plurality of ion-implanted regions PSD may be formed in the active region AC on both sides of the gate PG. Each of the plurality of ion-implanted regions PSD may constitute a source region or a drain region of the transistor TR.

The multilayer wiring structure MWS of the peripheral circuit structure PCS may include a plurality of contact plugs 72 and a plurality of conductive lines 74. At least some of the plurality of conductive lines 74 may be electrically connected to the transistor TR. The plurality of contact plugs 72 may connect each of the plurality of transistors TR to some of the plurality of conductive lines 74. The plurality of transistors TR and the multilayer wiring structure MWS, which are included in the peripheral circuit structure PCS, may be covered by an interlayer dielectric 70. The interlayer dielectric 70 may include, for example, a silicon oxide film, a silicon nitride film, an SiON film, an SiOCN film, or a combination thereof.

The plurality of circuits of the peripheral circuit structure PCS may include the various circuits of the peripheral circuit 30, which are described with reference to FIG. 1. In embodiments of the present inventive concept, the peripheral circuit structure PCS may further include unit elements, such as a resistor and a capacitor. The plurality of transistors TR, the plurality of contact plugs 72, and the plurality of conductive lines 74, which are included in the peripheral circuit structure PCS, may constitute the plurality of circuits. Each of the plurality of transistors TR may be configured to be electrically connected to the memory cell area MEC via the multilayer wiring structure MWS. Each common source line CSL of the cell array structure CAS may be spaced apart from the peripheral circuit structure PCS in the vertical direction (Z direction) with the memory cell area MEC therebetween.

Each of the plurality of bit lines BL may be connected to a wiring structure MS. The wiring structure MS may include a first upper wiring layer 172, a second upper wiring layer 174, and a third upper wiring layer 176. Each of the first upper wiring layer 172, the second upper wiring layer 174, and the third upper wiring layer 176 may include, for example, tungsten, titanium, tantalum, copper, aluminum, titanium nitride, tantalum nitride, tungsten nitride, or a combination thereof.

A plurality of first bonding metal pads 178A may be arranged on an upper surface of the cell array structure CAS, which is adjacent to the peripheral circuit structure PCS. The plurality of bit lines BL may be configured to be connected to the plurality of first bonding metal pads 178A via the wiring structure MS. In the cell array structure CAS, each of the wiring structure MS and the plurality of first bonding metal pads 178A may be covered by an interlayer dielectric 150. The interlayer dielectric 150 may include, for example, a silicon oxide film, a silicon nitride film, or a combination thereof.

The peripheral circuit structure PCS may be spaced apart from the plurality of channel structures 180 with the plurality of bit lines BL disposed therebetween. The peripheral circuit structure PCS may include a plurality of second bonding metal pads 178B that are arranged on the multilayer wiring structure MWS. The plurality of second bonding metal pads 178B may be connected to the plurality of circuits of the peripheral circuit structure PCS. In the peripheral circuit structure PCS, the interlayer dielectric 70 may cover the plurality of transistors TR, the plurality of conductive plugs 72, the plurality of conductive lines 74, and the plurality of second bonding metal pads 178B.

The plurality of second bonding metal pads 178B may be respectively bonded to and thus electrically connected to the plurality of first bonding metal pads 178A of the cell array structure CAS. The plurality of first bonding metal pads 178A and the plurality of second bonding metal pads 178B may constitute a plurality of bonding structures BS. Each of the plurality of bit lines BL may be connected to at least one circuit selected from the plurality of circuits of the peripheral circuit structure PCS via a bonding structure BS including the first bonding metal pad 178A and the second bonding metal pad 178B.

In embodiments of the present inventive concept, each of the plurality of conductive plugs 72 and the plurality of conductive lines 74 in the peripheral circuit structure PCS may include, but is not limited to, tungsten, aluminum, copper, or a combination thereof. The device isolation film 54 may include, for example, a silicon oxide film, a silicon nitride film, or a combination thereof. The interlayer dielectric 70 may include, for example, a silicon oxide film, a silicon nitride film, or a combination thereof. The plurality of first bonding metal pads 178A and the plurality of second bonding metal pads 178B, which constitute the plurality of bonding structures BS, may each include, for example, copper, aluminum, or tungsten.

In the cell array structure CAS, the common source line CSL may be covered by an insulating film 106. The insulating film 106 may include, for example, a silicon oxide film. The insulating film 106 may be covered by a protective film. For example, the protective film may include, but is not limited to, a polyimide material film, such as a photosensitive polyimide (PSPI).

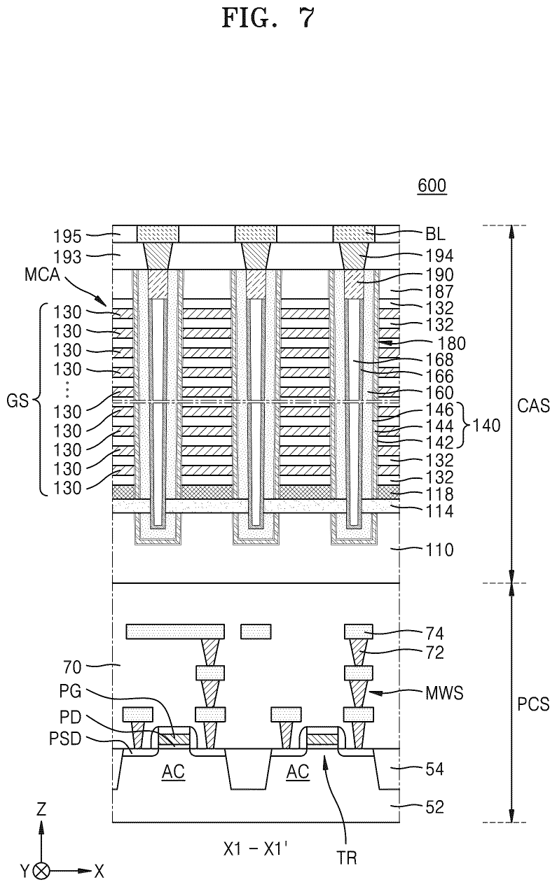

FIG. 7 is a cross-sectional view illustrating a semiconductor device 600 according to embodiments of the present inventive concept. In FIG. 7, the same reference numerals as in FIGS. 2A to 2E and 6 respectively denote the same members, and here, repeated descriptions thereof may be omitted or briefly discussed.

Referring to FIG. 7, the semiconductor device 600 may have substantially the same configuration as the semiconductor device 500 described with reference to FIG. 6. However, the cell array structure CAS of the semiconductor device 600 includes a cell substrate 110, which is arranged on the peripheral circuit structure PCS, and the gate stack GS, which is arranged on the cell substrate 110.

In the cell array structure CAS, a first conductive plate 114 and a second conductive plate 118 may be sequentially arranged in the stated order on the cell substrate 110, and the gate stack GS including the plurality of gate lines 130 may be arranged on the second conductive plate 118.

The cell substrate 110, the first conductive plate 114, and the second conductive plate 118 may function as the common source line CSL (see FIG. 1) for supplying currents to vertical memory cells that are included in the cell array structure CAS.

In embodiments of the present inventive concept, the cell substrate 110 may include a semiconductor material, such as doped polysilicon. Each of the first conductive plate 114 and the second conductive plate 118 may include, for example, a doped polysilicon film, a metal film, or a combination thereof. For example, the metal film may include, but is not limited to, tungsten (W). The insulating pattern 132 may be arranged between the second conductive plate 118 and the plurality of gate lines 130 and between the plurality of gate lines 130.

In the semiconductor device 600, the peripheral circuit structure PCS may be spaced apart from the bit line BL with the plurality of gate lines 130 disposed therebetween. The cell substrate 110 may be arranged between the peripheral circuit structure PCS and the first conductive plate 114. The plurality of channel structures 180 may pass through the second conductive plate 118 in the vertical direction (Z direction) and may partially pass through the cell substrate 110 in the vertical direction (Z direction) to extend lengthwise in the vertical direction (Z direction). The channel layer 166 and the insulating plug 168 of each of the plurality of channel structures 180 may pass through the first conductive plate 114 and the second conductive plate 118 in the vertical direction (Z direction) and may partially pass through the cell substrate 110 in the vertical direction to extend lengthwise in the vertical direction (Z direction). The first conductive plate 114 may pass through the multi-tunneling dielectric structure 140 and the ferroelectric layer 160 in the horizontal direction to contact a sidewall of the channel layer 166.

Next, methods of fabricating semiconductor devices, according to embodiments of the present inventive concept, are described in detail.

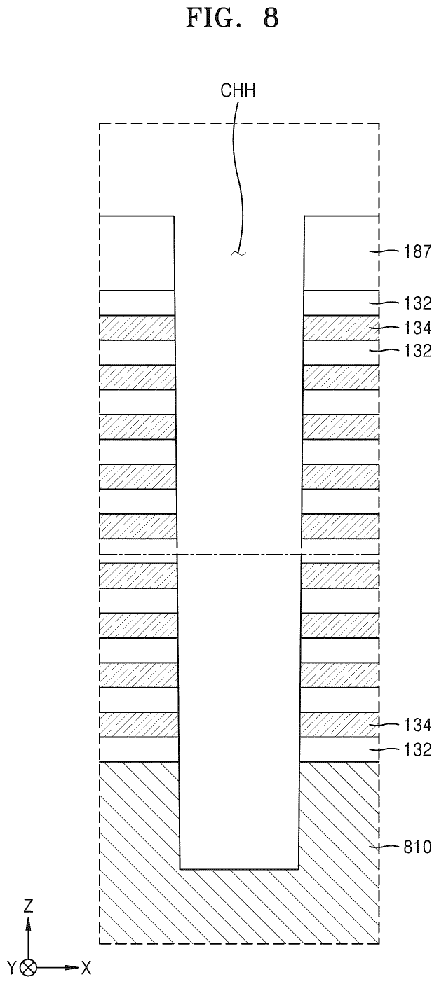

FIGS. 8 to 18 are cross-sectional views respectively illustrating a sequence of processes of a method of fabricating a semiconductor device, according to embodiments of the present inventive concept. FIGS. 8 to 18 each illustrate an enlarged cross-sectional configuration of a region corresponding to the region EX1 of FIG. 2B according to the sequence of processes. An example of a method of fabricating the semiconductor device 100 shown in FIGS. 2A to 2E is described with reference to FIGS. 8 to 18. In FIGS. 8 to 18, the same reference numerals as in FIGS. 2A to 2E respectively denote the same members, and here, repeated descriptions thereof may be omitted or briefly discussed.

Referring to FIG. 8, a plurality of insulating films and a plurality of sacrificial insulating films may be alternately stacked one-by-one on a sacrificial substrate 810, and then, the intermediate insulating film 187 may be formed on an uppermost insulating film from among the plurality of insulating films. Next, the vertical hole CHH may be formed to pass through the plurality of insulating films, the plurality of sacrificial insulating films, and the intermediate insulating film 187 and extend in the vertical direction (Z direction), thereby forming the plurality of insulating patterns 132 and a plurality of sacrificial patterns 134 to define the vertical hole CHH. The vertical hole CHH may be formed to partially pass through the sacrificial substrate 810.

The sacrificial substrate 810 may include, for example, silicon. For example, the plurality of insulating patterns 132 may each include a silicon oxide film, and the plurality of sacrificial patterns 134 may each include a silicon nitride film. Each of the plurality of sacrificial patterns 134 may function to secure a space for forming the gate stack GS (see FIGS. 2B and 2C) in a subsequent process.

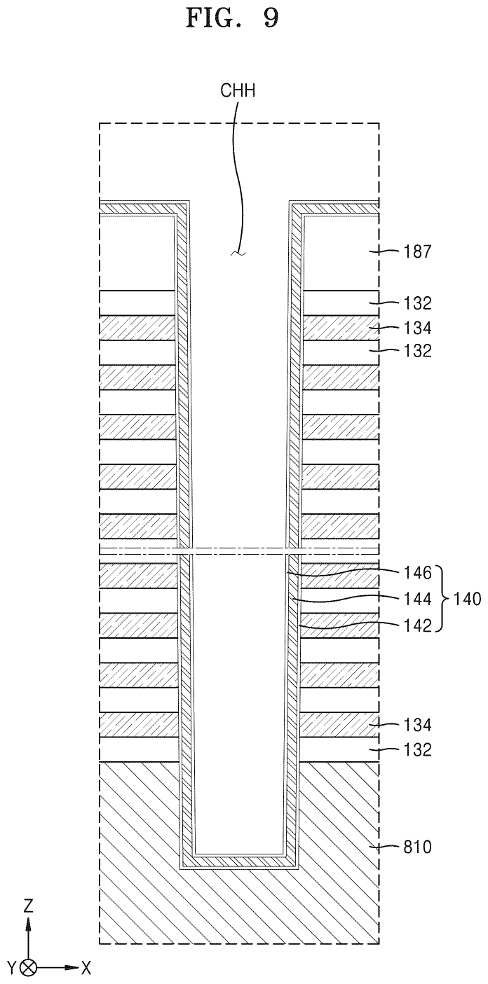

Referring to FIG. 9, in the resulting product of FIG. 8, the multi-tunneling dielectric structure 140 may be formed to include the first silicon oxide film 142, the silicon oxynitride film 144, and the second silicon oxide film 146, which are sequentially stacked in the stated order on exposed surfaces inside and outside the vertical hole CHH. For example, the first silicon oxide film 142, silicon oxynitride film 144, and second silicon oxide film 146 may form a concentric annular cylindrical structure that extends in the vertical direction (Z direction).

In embodiments of the present inventive concept, to form the multi-tunneling dielectric structure 140, the first silicon oxide film 142, the silicon oxynitride film 144, and the second silicon oxide film 146 may be sequentially formed in the stated order by an atomic layer deposition (ALD) process. In embodiments of the present inventive concept, to form the multi-tunneling dielectric structure 140, a silicon oxide film may be formed to cover the exposed surfaces inside and outside the vertical hole CHH in the resulting product of FIG. 8, and nitrogen atoms may be implanted into an inner portion of the silicon oxide film, which is spaced apart from an exposed surface of the silicon oxide film, by an ion implantation process, whereby the silicon oxynitride film 144 may be formed from the inner portion of the silicon oxide film. The remaining portions of the silicon oxide film, which are not implanted with nitrogen atoms, that is, the other portions of the silicon oxide film, which are spaced apart from each other with the silicon oxynitride film 144 disposed therebetween, may respectively constitute the first silicon oxide film 142 and the second silicon oxide film 146.

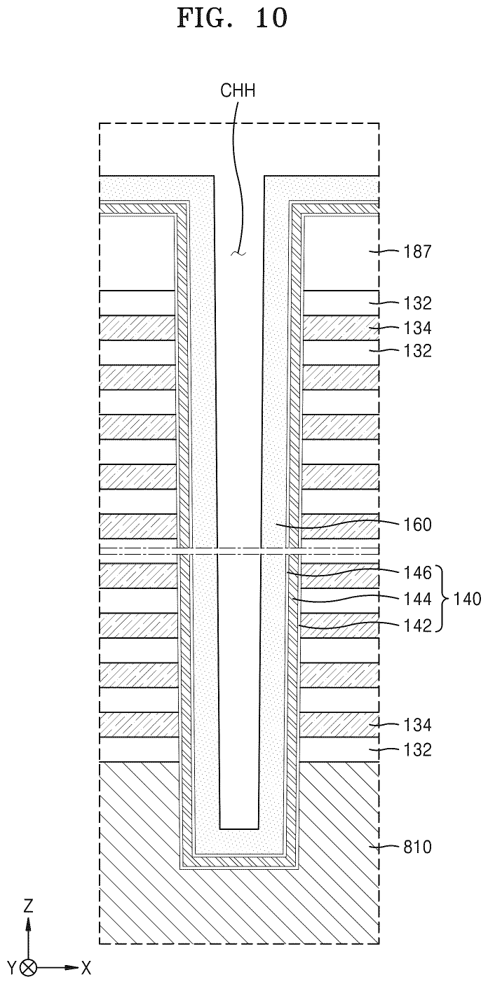

Referring to FIG. 10, in the resulting product of FIG. 9, the ferroelectric layer 160 may be formed to conformally cover an exposed surface of the second silicon oxide film 146. For example, an ALD process may be used to form the ferroelectric layer 160.

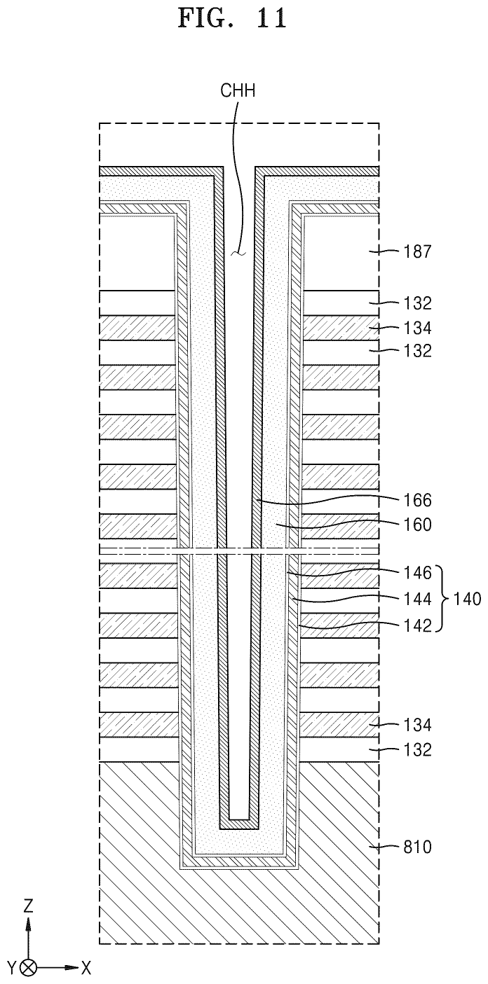

Referring to FIG. 11, in the resulting product of FIG. 10, the channel layer 166 may be formed to conformally cover an exposed surface of the ferroelectric layer 160. For example, an ALD process may be used to form the ferroelectric layer 160.

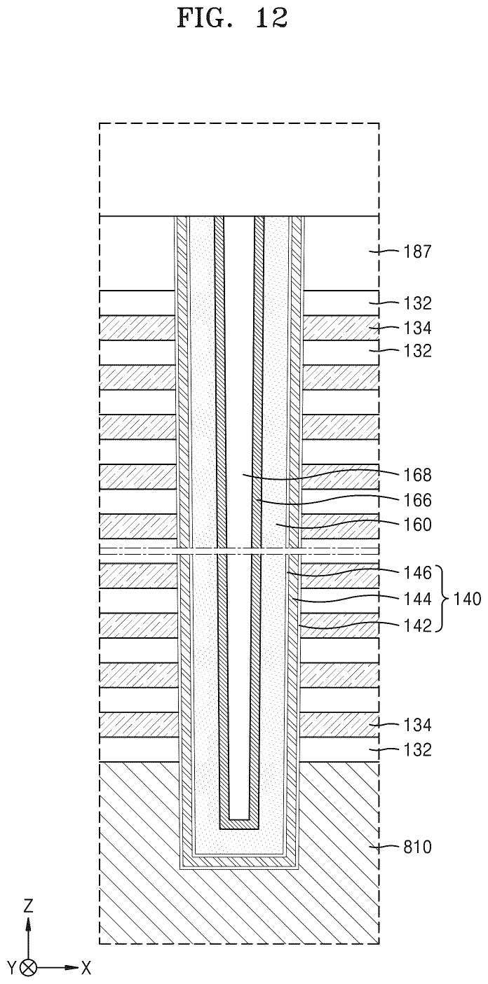

Referring to FIG. 12, in the resulting product of FIG. 11, the insulating plug 168 may be formed on the channel layer 166 to fill the remaining inner space of the vertical hole CHH, followed by planarizing an obtained resulting product, thereby exposing the upper surface of the intermediate insulating film 187. For example, an ALD process or a chemical vapor deposition (CVD) process may be used to form the insulating plug 168. For example, a chemical mechanical polishing (CMP) process may be used to perform the planarization.

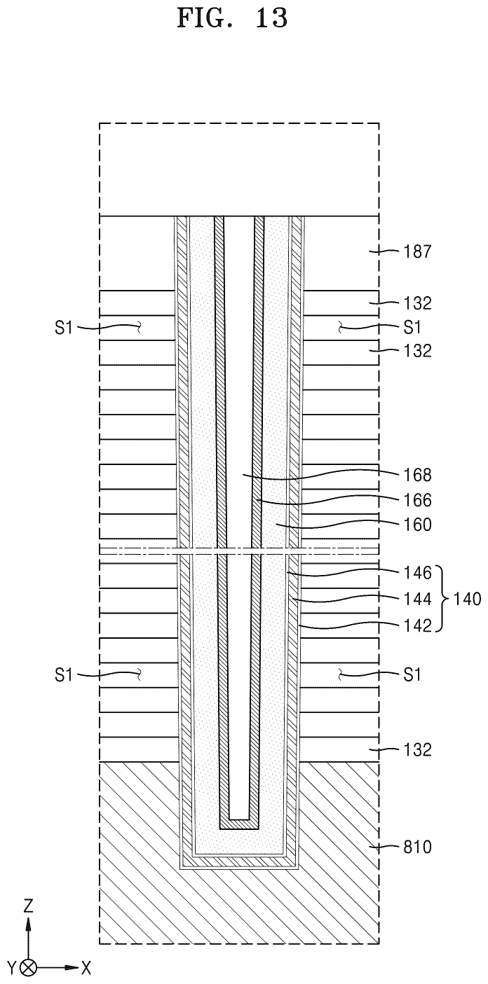

Referring to FIG. 13, the plurality of sacrificial patterns 134 may be removed from the resulting product of FIG. 12, thereby forming a plurality of gate spaces S1 between the insulating patterns 132. To form the plurality of gate spaces S1, the plurality of word line cut regions WLC described with reference to FIG. 2A may be formed in advance, and the plurality of sacrificial patterns 134 may be removed through the plurality of word line cut regions WLC. After the plurality of sacrificial patterns 134 are removed, the first silicon oxide film 142 may be exposed by the plurality of gate spaces S1.

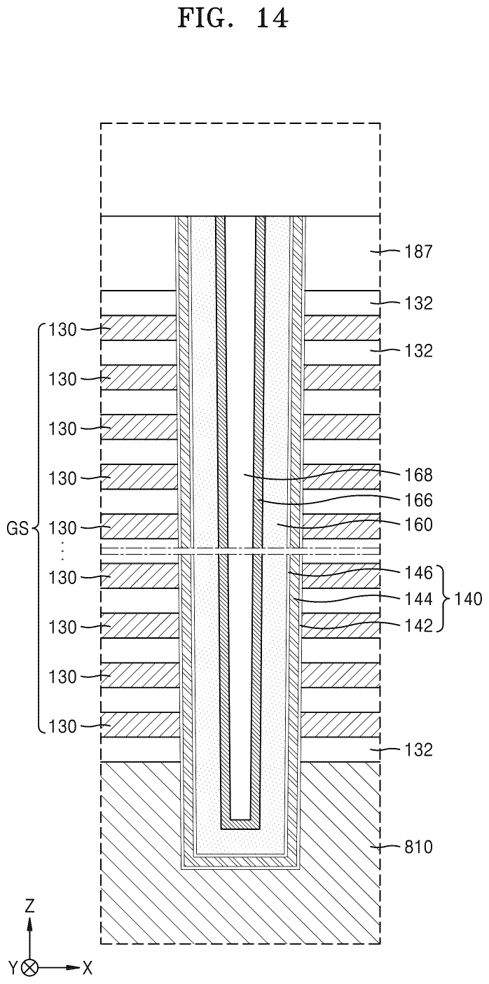

Referring to FIG. 14, in the resulting product of FIG. 13, the plurality of gate spaces S1 may be respectively filled with the plurality of gate lines 130. Next, as shown in FIG. 2A, the inside of each of the plurality of word line cut regions WLC may be filled with the word line cut structure 192.

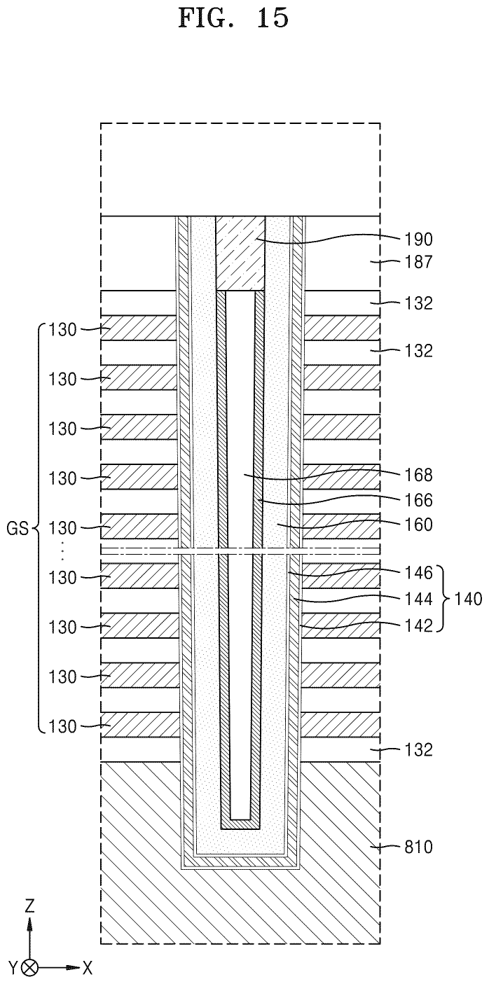

Referring to FIG. 15, a space may be formed in an upper portion of the vertical hole CHH by removing a portion of each of the channel layer 166 and the insulating plug 168 from the resulting product of FIG. 14, and the conductive pad 190 may be formed to fill the space.

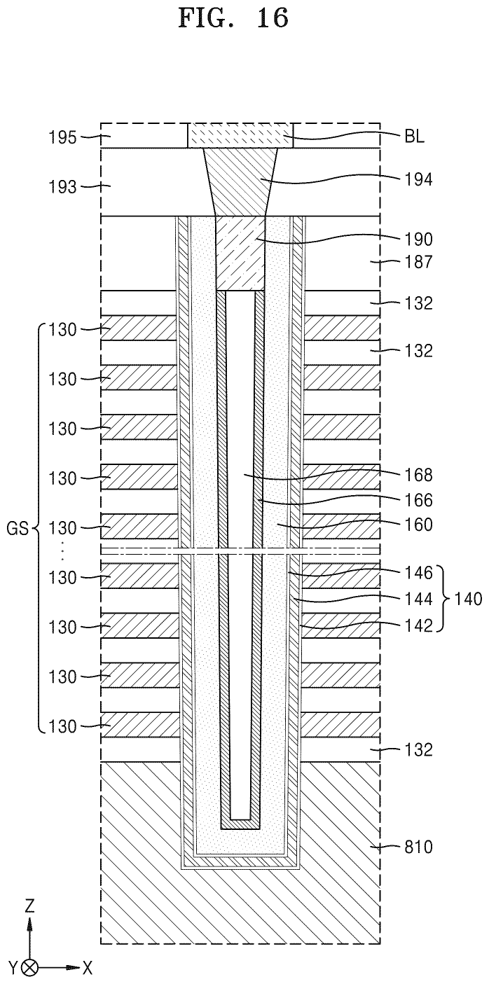

Referring to FIG. 16, the first upper insulating film 193, which covers the intermediate insulating film 187 and the conductive pad 190, and the bit line contact pad 194, which passes through the first upper insulating film 193 and is connected to the conductive pad 190, may be formed on the resulting product of FIG. 15. Next, the second upper insulating film 195 may be formed to cover the first upper insulating film 193 and the bit line contact pad 194, and the bit line BL may be formed to pass through the second upper insulating film 195 and be connected to the bit line contact pad 194.

In embodiments of the present inventive concept, to fabricate the semiconductor device 500 shown in FIG. 6, the wiring structure MS, the plurality of first bonding metal pads 178A, and the interlayer dielectric 150 filling spaces between the wiring structure MS and the plurality of first bonding metal pads 178A may be formed on or over the bit line BL. The wiring structure MS may include the plurality of first upper wiring layers 172, the plurality of second upper wiring layers 174, and the plurality of third upper wiring layers 176. In addition, the peripheral circuit structure PCS shown in FIG. 6 may be formed, and the plurality of bonding structures BS may be formed by respectively bonding the plurality of first bonding metal pads 178A of the cell array structure CAS to the plurality of second bonding metal pads 178B of the peripheral circuit structure PCS, thereby bonding the cell array structure CAS onto the peripheral circuit structure PCS.

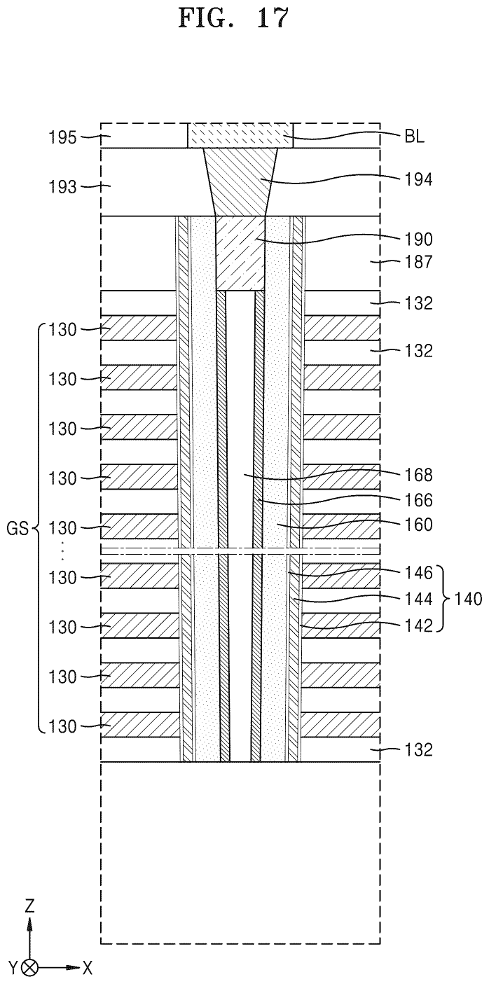

Referring to FIG. 17, a resulting product obtained by removing the sacrificial substrate 810 from the resulting product of FIG. 16 may be planarized, thereby exposing the insulating pattern 132, the multi-tunneling dielectric structure 140, the ferroelectric layer 160, the channel layer 166, and the insulating plug 168.

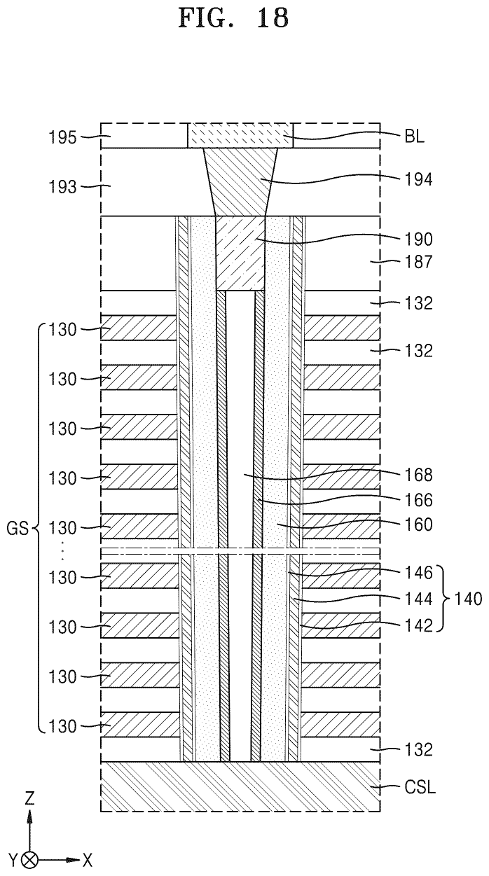

Referring to FIG. 18, in the resulting product of FIG. 17, the common source line CSL may be formed to cover exposed surfaces of the insulating pattern 132, the multi-tunneling dielectric structure 140, the ferroelectric layer 160, the channel layer 166, and the insulating plug 168.

In embodiments of the present inventive concept, to fabricate the semiconductor device 500 shown in FIG. 6, the insulating film 106 may be formed to cover the common source line CSL, as shown in FIG. 6.

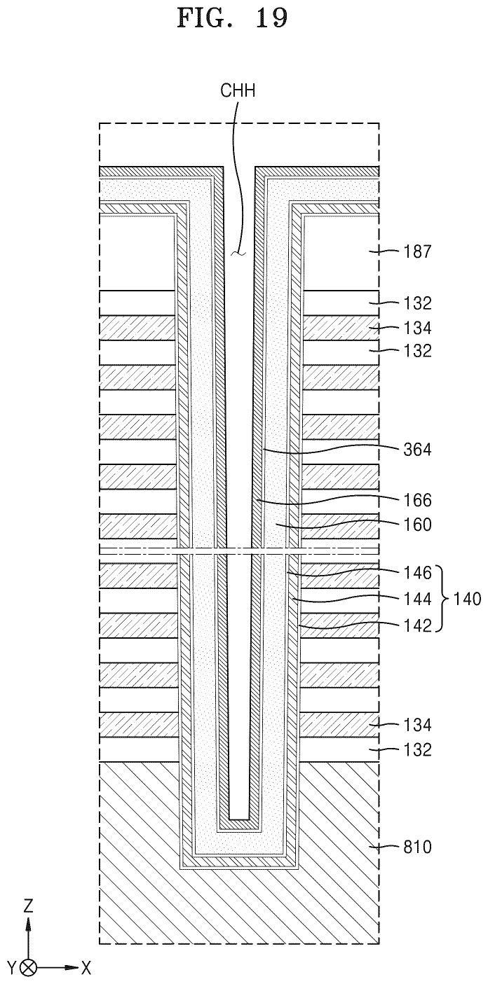

FIG. 19 is a cross-sectional view illustrating a method of fabricating a semiconductor device, according to embodiments of the present inventive concept. FIG. 19 illustrates an enlarged cross-sectional configuration of a region corresponding to the region EX1 of FIG. 2B according to a sequence of processes. An example of a method of fabricating the semiconductor device 300 shown in FIGS. 4A and 4B is described with reference to FIG. 19. In FIG. 19, the same reference numerals as in FIGS. 2A to 18 respectively denote the same members, and here, repeated descriptions thereof may be omitted or briefly discussed.

Referring to FIG. 19, the processes described with reference to FIGS. 8 to 10 may be performed. Next, in the resulting product of FIG. 10, the channel oxide film 364 may be formed to conformally cover an exposed surface of the ferroelectric layer 160. For example, an ALD process may be used to form the channel oxide film 364. Next, the channel layer 166 may be formed on the channel oxide film 364 in a similar manner to that described with reference to FIG. 11.

Next, the processes described with reference to FIGS. 12 to 18 may be performed on the resulting product of FIG. 19, thereby fabricating the semiconductor device 300 shown in FIGS. 4A and 4B.

Heretofore, although the examples of the methods of fabricating the semiconductor device 100 shown in FIGS. 2A to 2E, the semiconductor device 300 shown in FIGS. 4A and 4B, and the semiconductor device 500 shown in FIG. 6 have been described with reference to FIGS. 8 to 19, it will be understood by those of ordinary skill in the art that semiconductor devices having various structures that are obtained by making various modifications and changes to the examples that are described with reference to FIGS. 8 to 19 without departing from the spirit and scope of the present inventive concept may be fabricated.

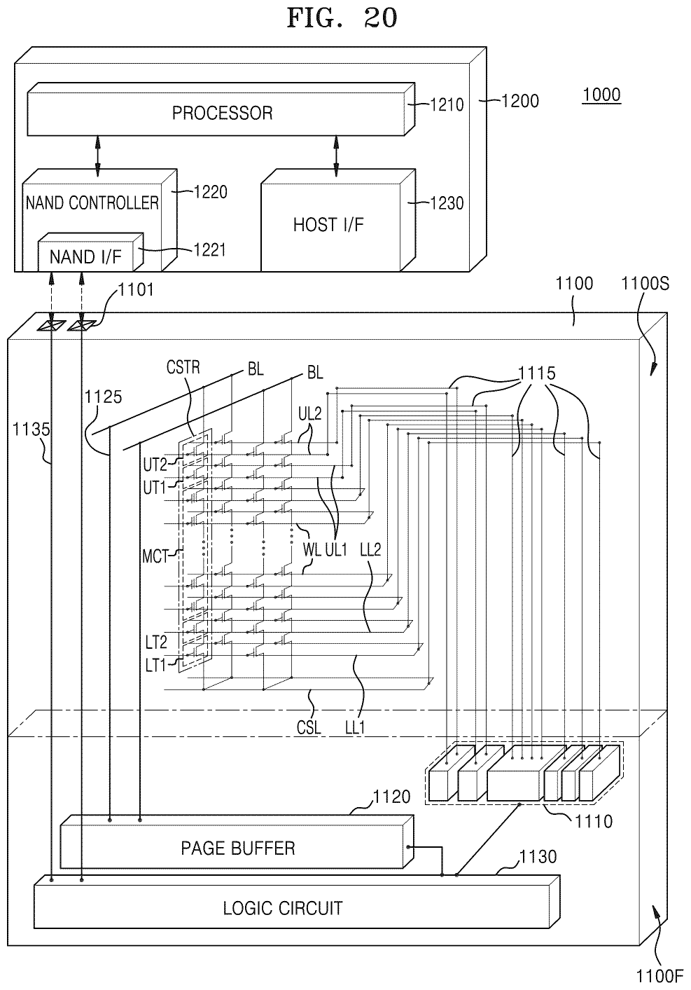

FIG. 20 is a diagram schematically illustrating an electronic system including a semiconductor device, according to embodiments of the present inventive concept.

Referring to FIG. 20, an electronic system 1000 according to an embodiment of the present inventive concept may include a semiconductor device 1100 and a controller 1200 that is electrically connected to the semiconductor device 1100. The electronic system 1000 may include a storage device, which includes one or more semiconductor devices 1100, or may include an electronic device including the storage device. For example, the electronic system 1000 may include a solid-state drive (SSD) device, a universal serial bus (USB), a computing system, a medical device, or a communication device, which includes at least one semiconductor device 1100.

The semiconductor device 1100 may include a nonvolatile memory device. For example, the semiconductor device 1100 may include a NAND flash memory device including at least one of the structures of the semiconductor devices 100, 200, 300, 300A, 300B, 400, 500, and 600 described with reference to FIGS. 2A to 7. The semiconductor device 1100 may include a first structure 1100F and a second structure 1100S that is disposed on the first structure 1100F. In embodiments of the present inventive concept, the first structure 1100F may be arranged beside (or, e.g., adjacent to) the second structure 1100S. The first structure 1100F may include a peripheral circuit structure, which includes a decoder circuit 1110, a page buffer 1120, and a logic circuit 1130. The second structure 1100S may include a memory cell structure, which includes the bit line BL, the common source line CSL, the plurality of word lines WL, first and second gate upper lines UL1 and UL2, first and second gate lower lines LL1 and LL2, and a plurality of memory cell strings CSTR between the bit line BL and the common source line CSL.

In the second structure 1100S, each of the plurality of memory cell strings CSTR may include lower transistors LT1 and LT2, which are adjacent to the common source line CSL, upper transistors UT1 and UT2, which are adjacent to the bit line BL, and a plurality of memory cell transistors MCT that are between the lower transistors LT1 and LT2 and the upper transistors UT1 and UT2. The memory cell transistors MCT may be electrically connected between the lower transistors LT1 and LT2 and the upper transistors UT1 and UT2. The respective numbers of lower transistors LT1 and LT2 and upper transistors UT1 and UT2 may be variously modified depending on embodiments.

In embodiments of the present inventive concept, the upper transistors UT1 and UT2 may include a string select transistor, and the lower transistors LT1 and LT2 may include a ground select transistor. A plurality of gate lower lines (that is, LL1 and LL2) may be gate electrodes of the lower transistors LT1 and LT2, respectively. The word line WL may be a gate electrode of a memory cell transistor MCT, and the gate upper lines UL1 and UL2 may be gate electrodes of the upper transistors UT1 and UT2, respectively.

The common source line CSL, the plurality of gate lower lines (that is, LL1 and LL2), the plurality of word lines WL, and a plurality of gate upper lines (that is, UL1 and UL2) may be electrically connected to the decoder circuit 1110 via a plurality of first connection wiring lines 1115, which extend from inside the first structure 1100F to the second structure 1100S. The plurality of bit lines BL may be electrically connected to the page buffer 1120 via a plurality of second connection wiring lines 1125, which extend from inside the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 via an input/output pad 1101 that is electrically connected with the logic circuit 1130. The input/output pad 1101 may be electrically connected with the logic circuit 1130 via an input/output connection wiring line 1135, which extends from inside the first structure 1100F to the second structure 1100S.

The controller 1200 may include a processor 1210, a NAND controller 1220, and a host interface 1230. Depending on embodiments of the present inventive concept, the electronic system 1000 may include a plurality of semiconductor devices 1100, and in this case, the controller 1200 may control the plurality of semiconductor devices 1100.

The processor 1210 may control overall operations of the electronic system 1000 including the controller 1200. The processor 1210 may be operated according to certain firmware and may access the semiconductor device 1100 by controlling the NAND controller 1220. The NAND controller 1220 may include a NAND interface 1221 for processing communication with the semiconductor device 1100. Via the NAND interface 1221, a control command for controlling the semiconductor device 1100, data intended to be written to the plurality of memory cell transistors MCT of the semiconductor device 1100, data intended to be read from the plurality of memory cell transistors MCT of the semiconductor device 1100, and the like may be transmitted. The host interface 1230 may provide a function of communication between the electronic system 1000 and an external host. When receiving a control command from the external host via the host interface 1230, the processor 1210 may control the semiconductor device 1100 in response to the control command.

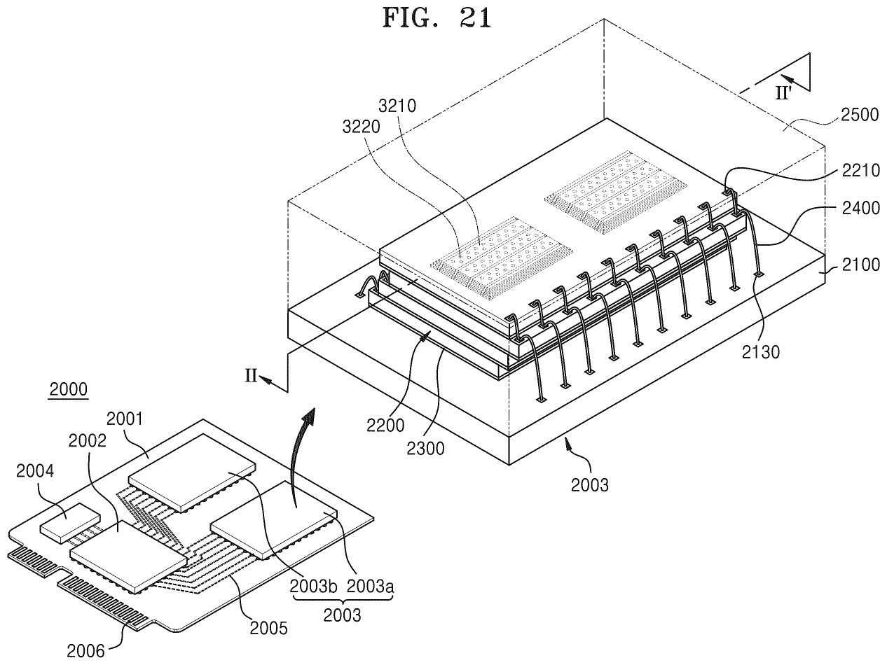

FIG. 21 is a perspective view schematically illustrating an electronic system including a semiconductor device, according to embodiments of the present inventive concept.

Referring to FIG. 21, an electronic system 2000 according to an embodiment of the present inventive concept may include a main substrate 2001, and a controller 2002, one or more semiconductor packages 2003, and DRAM 2004, which are mounted on the main substrate 2001. The semiconductor packages 2003 and the DRAM 2004 may be connected to the controller 2002 by a plurality of wiring patterns 2005 that are formed on the main substrate 2001.

The main substrate 2001 may include a connector 2006 including a plurality of pins to be coupled to an external host. The number of pins and the arrangement of the plurality of pins, in the connector 2006, may vary depending on a communication interface between the electronic system 2000 and the external host. In embodiments of the present inventive concept, the electronic system 2000 may communicate with the external host according to one of interfaces, such as Universal Serial Bus (USB), Peripheral Component Interconnect Express (PCI-Express), Serial Advanced Technology Attachment (SATA), and M-Phy for Universal Flash Storage (UFS). In embodiments of the present inventive concept, the electronic system 2000 may be operated by power supplied from the external host via the connector 2006. The electronic system 2000 may further include a power management integrated circuit (PMIC) distributing the power, which is supplied from the external host, to the controller 2002 and the semiconductor packages 2003.

The controller 2002 may write data to or read data from the semiconductor packages 2003 and may increase an operation speed of the electronic system 2000.

The DRAM 2004 may be a buffer memory for alleviating a speed difference between the external host and the semiconductor packages 2003 corresponding to data storage spaces. The DRAM 2004 in the electronic system 2000 may operate as a kind of cache memory and may provide a space for temporarily storing data in a control operation on the semiconductor packages 2003. When the DRAM 2004 is included in the electronic system 2000, the controller 2002 may further include a DRAM controller for controlling the DRAM 2004, in addition to a NAND controller for controlling the semiconductor packages 2003.

The semiconductor packages 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 on a lower surface of each of the plurality of semiconductor chips 2200, a connection structure 2400 electrically connecting the plurality of semiconductor chips 2200 with the package substrate 2100, and a molding layer 2500 arranged on the package substrate 2100 to cover the plurality of semiconductor chips 2200 and the connection structure 2400.

The package substrate 2100 may include a printed circuit board including a plurality of package upper pads 2130. Each of the plurality of semiconductor chips 2200 may include an input/output pad 2210. The input/output pad 2210 may correspond to the input/output pad 1101 of FIG. 20. Each of the plurality of semiconductor chips 2200 may include a plurality of gate stacks 3210 and a plurality of channel structures 3220. Each of the plurality of semiconductor chips 2200 may include at least one of the structures of the semiconductor devices 100, 200, 300, 300A, 300B, 400, 500, and/or 600 described with reference to FIGS. 2A to 7.

In embodiments of the present inventive concept, the connection structure 2400 may include a bonding wire electrically connecting the input/output pad 2210 with a package upper pad 2130. Therefore, in the first and second semiconductor packages 2003a and 2003b, the plurality of semiconductor chips 2200 may be electrically connected to each other in a bonding wire manner and may be electrically connected to the package upper pads 2130 of the package substrate 2100. In embodiments of the present inventive concept, in the first and second semiconductor packages 2003a and 2003b, the plurality of semiconductor chips 2200 may be electrically connected to each other by a connection structure including a through-silicon via (TSV) rather than by the connection structure 2400 of a bonding wire type.

In embodiments of the present inventive concept, the controller 2002 and the plurality of semiconductor chips 2200 may be included in one package. In embodiments of the present inventive concept, the controller 2002 and the plurality of semiconductor chips 2200 may be mounted on a separate interposer substrate, which is different from the main substrate 2001, and may be connected to each other by wiring lines that are formed on the interposer substrate.

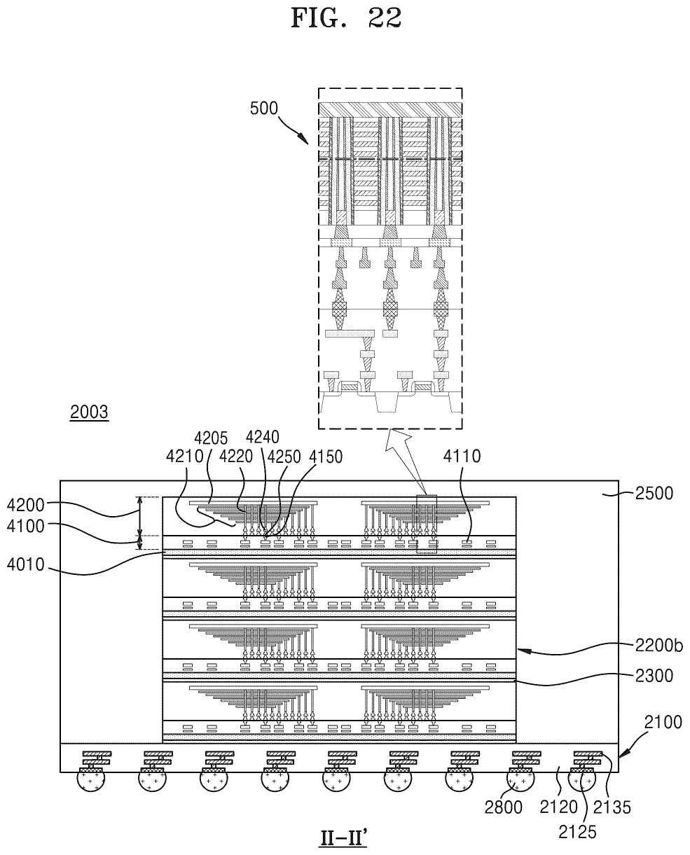

FIG. 22 is a cross-sectional view schematically illustrating semiconductor packages according to embodiments of the present inventive concept. FIG. 22 illustrates a configuration corresponding to the cross-section taken along the line II-II′ of FIG. 21, in more detail.

Referring to FIG. 22, in the semiconductor package 2003, a plurality of semiconductor chips 2200b may each include a semiconductor substrate 4010, a first structure 4100 on the semiconductor substrate 4010, and a second structure 4200 arranged on the first structure 4100 to be bonded to the first structure 4100 in a wafer bonding manner.

The first structure 4100 may include a peripheral circuit area including peripheral wiring lines 4110 and first bonding structures 4150. The second structure 4200 may include a common source line 4205, a gate stack structure 4210 between the common source line 4205 and the first structure 4100, memory channel structures 4220 passing through the gate stack structures 4210, and second bonding structures 4250 respectively and electrically connected to the memory channel structures 4220 and the word lines WL (see FIG. 20) of the gate stack structure 4210. For example, the second bonding structures 4250 may be respectively and electrically connected to the memory channel structures 4220 and the word lines WL (see FIG. 20) via bit lines 4240, which are electrically connected to the memory channel structures 4220, and gate connection wiring lines electrically connected to the word lines WL (see FIG. 20). The first bonding structures 4150 of the first structure 4100 may be brought into contact with and bonded to the second bonding structures 4250 of the second structure 4200, respectively. Bonded portions of the first bonding structures 4150 and the second bonding structures 4250 may include, for example, copper (Cu).

Each of the plurality of semiconductor chips 2200b may further include the input/output pad 2210 (see FIG. 21) that is electrically connected to peripheral wiring lines 4110 of the first structure 4100.

Electrical connections between the plurality of semiconductor chips 2200 of FIG. 21 as well as electrical connections between the plurality of semiconductor chips 2200b of FIG. 22 may be made by the connection structure 2400 of a bonding wire type. However, in embodiments of the present inventive concept, semiconductor chips in one semiconductor package, such as the plurality of semiconductor chips 2200 of FIG. 21 and the plurality of semiconductor chips 2200b of FIG. 22, may be electrically connected to each other by a connection structure including a TSV.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor device comprising:
a gate line;
a hole extending through the gate line;
a channel layer extending lengthwise in a first direction in the hole;
a ferroelectric layer arranged between the channel layer and the gate line and extending lengthwise in the first direction in the hole; and
a multi-tunneling dielectric structure arranged between the ferroelectric layer and the gate line and extending lengthwise in the first direction in the hole,
wherein the multi-tunneling dielectric structure comprises:
a first silicon oxide film contacting the gate line;
a second silicon oxide film spaced apart from the first silicon oxide film in a second direction and contacting the ferroelectric layer, wherein the second direction crosses the first direction; and
a silicon oxynitride film disposed between the first silicon oxide film and the second silicon oxide film.

2. The semiconductor device of claim 1, wherein, in the multi-tunneling dielectric structure, a thickness of the silicon oxynitride film is greater than a thickness of each of the first silicon oxide film and the second silicon oxide film.

3. The semiconductor device of claim 1, wherein, in the multi-tunneling dielectric structure, a first thickness of the first silicon oxide film is substantially equal to a second thickness of the second silicon oxide film.

4. The semiconductor device of claim 1, wherein, in the multi-tunneling dielectric structure, a thickness of the silicon oxynitride film is greater than a thickness of each of the first silicon oxide film and the second silicon oxide film, and
wherein a first thickness of the first silicon oxide film is different from a second thickness of the second silicon oxide film.

5. The semiconductor device of claim 1, wherein a second thickness of the second silicon oxide film is greater than a first thickness of the first silicon oxide film.

6. The semiconductor device of claim 1, wherein, in the multi-tunneling dielectric structure, a nitrogen atom content in the silicon oxynitride film gradually increases toward a center portion of the silicon oxynitride film from a sidewall of the silicon oxynitride film, which is in contact with the first silicon oxide film, and also toward the center portion of the silicon oxynitride film from a sidewall of the silicon oxynitride film, which is in contact with the second silicon oxide film.

7. The semiconductor device of claim 1, wherein, in the multi-tunneling dielectric structure, the silicon oxynitride film comprises a first side portion comprising a first oxygen-rich SiON that is in contact with the first silicon oxide film, a second side portion comprising a second oxygen-rich SiON that is in contact with the second silicon oxide film, and a center portion arranged between the first side portion and the second side portion and comprising nitrogen-rich SiON.

8. The semiconductor device of claim 1, wherein the channel layer comprises polysilicon, an oxide semiconductor, a 2-dimensional semiconductor material, or a combination thereof, and
wherein the gate line comprises a metal, a conductive metal nitride, a metal silicide, an impurity-doped semiconductor, or a combination thereof.

9. The semiconductor device of claim 1, further comprising at least one of a channel oxide film, a silicon nitride film, or a third silicon oxide film,
wherein the channel oxide film is arranged between the channel layer and the ferroelectric layer,
wherein the silicon nitride film is arranged between the multi-tunneling dielectric structure and the ferroelectric layer, and
wherein the third silicon oxide film is arranged between the multi-tunneling dielectric structure and the ferroelectric layer and is spaced apart from the multi-tunneling dielectric structure.

10. The semiconductor device of claim 1, further comprising a channel oxide film arranged between the channel layer and the ferroelectric layer and extending lengthwise in the hole, and
wherein the channel oxide film comprises an inner sidewall, which is in contact with the channel layer, and an outer sidewall, which is in contact with the ferroelectric layer.

11. A semiconductor device comprising:
a stack structure comprising a plurality of gate lines, which are spaced apart from each other in a vertical direction, and a plurality of insulating patterns alternately arranged with the plurality of gate lines;
a channel layer, which extends lengthwise in the vertical direction in a vertical hole that passes through the stack structure in the vertical direction;
a ferroelectric layer arranged between the channel layer and the stack structure and extending lengthwise in the vertical direction in the vertical hole; and
a multi-tunneling dielectric structure arranged between the ferroelectric layer and the stack structure and extending lengthwise in the vertical direction in the vertical hole,
wherein the multi-tunneling dielectric structure comprises:
a first silicon oxide film contacting the plurality of gate lines;
a second silicon oxide film spaced apart from the first silicon oxide film in a horizontal direction and contacting the ferroelectric layer; and
a silicon oxynitride film disposed between the first silicon oxide film and the second silicon oxide film.

12. The semiconductor device of claim 11, wherein a thickness of the silicon oxynitride film is greater than a thickness of each of the first silicon oxide film and the second silicon oxide film, and
wherein a nitrogen atom content in the silicon oxynitride film gradually increases toward a center portion of the silicon oxynitride film from a sidewall of the silicon oxynitride film, which is in contact with the first silicon oxide film, and also toward the center portion of the silicon oxynitride film from a sidewall of the silicon oxynitride film, which is in contact with the second silicon oxide film.

13. The semiconductor device of claim 11, wherein a thickness of the silicon oxynitride film is greater than a thickness of each of the first silicon oxide film and the second silicon oxide film, and the thickness of the first silicon oxide film is substantially equal to the thickness of the second silicon oxide film.

14. The semiconductor device of claim 11, wherein a thickness of the silicon oxynitride film is greater than a thickness of each of the first silicon oxide film and the second silicon oxide film, and the thickness of the second silicon oxide film is greater than the thickness of the first silicon oxide film.

15. The semiconductor device of claim 11, wherein, in the multi-tunneling dielectric structure, each of the first silicon oxide film, the silicon oxynitride film, and the second silicon oxide film has an annular cylindrical structure, and
wherein the second silicon oxide film is arranged in a space defined by the silicon oxynitride film, wherein the second silicon oxide film and the silicon oxynitride film are arranged in a space defined by the first silicon oxide film, and wherein the channel layer is arranged in a space defined by the second silicon oxide film.

16. The semiconductor device of claim 11, further comprising:
a channel oxide film arranged between the channel layer and the ferroelectric layer and extending lengthwise in the vertical direction in the vertical hole; and
a silicon nitride film arranged between the multi-tunneling dielectric structure and the ferroelectric layer and contacting the multi-tunneling dielectric structure.

17. The semiconductor device of claim 11, further comprising:
a channel oxide film arranged between the channel layer and the ferroelectric layer and extending lengthwise in the vertical direction in the vertical hole;
a silicon nitride film arranged between the multi-tunneling dielectric structure and the ferroelectric layer and contacting the multi-tunneling dielectric structure; and
a third silicon oxide film arranged between the multi-tunneling dielectric structure and the ferroelectric layer and spaced apart from the multi-tunneling dielectric structure,
wherein the channel oxide film comprises a silicon oxide film, a silicon oxynitride film, a high-K film having a dielectric constant that is greater than a dielectric constant of the silicon oxide film, or a combination thereof.

18. The semiconductor device of claim 11, wherein each of the plurality of gate lines comprises a metal, a conductive metal nitride, a metal silicide, an impurity-doped semiconductor, or a combination thereof,
wherein the channel layer comprises polysilicon, an oxide semiconductor, a 2-dimensional semiconductor material, or a combination thereof, and
wherein the ferroelectric layer comprises an oxide of at least one of Hf, Si, Al, Zr, Y, La, Gd, or Sr.

19. An electronic system comprising:
a main substrate;
a semiconductor device disposed on the main substrate; and
a controller arranged on the main substrate and electrically connected with the semiconductor device,
wherein the semiconductor device comprises:
a gate line;
a hole in the gate line;
a channel layer extending lengthwise in a first direction in the hole;
a ferroelectric layer arranged between the channel layer and the gate line and extending lengthwise in the first direction in the hole; and
a multi-tunneling dielectric structure arranged between the ferroelectric layer and the gate line and extending lengthwise in the first direction in the hole,
and wherein the multi-tunneling dielectric structure comprises:
a first silicon oxide film disposed on the gate line;
a second silicon oxide film disposed on the ferroelectric layer; and
a silicon oxynitride film disposed between the first silicon oxide film and the second silicon oxide film.

20. The electronic system of claim 19, wherein the main substrate further comprises wiring patterns electrically connecting the semiconductor device with the controller,
wherein, in the multi-tunneling dielectric structure, a thickness of the silicon oxynitride film in a second direction crossing the first direction is greater than a thickness of each of the first silicon oxide film and the second silicon oxide film in the second direction, and
wherein a nitrogen atom content in the silicon oxynitride film gradually increases toward a center portion of the silicon oxynitride film in the second direction from a sidewall of the silicon oxynitride film, which is in contact with the first silicon oxide film, and also toward the center portion of the silicon oxynitride film in the second direction from a sidewall of the silicon oxynitride film, which is in contact with the second silicon oxide film.
